(19) United States
(12) Patent Application Publication
(10) Pub. No.: US 2013/0128434 A1
(43) Pub. Date: May 23, 2013

(54) COLORED GLASS HOUSING

(71) Applicant: ASAHI GLASS COMPANY, LIMITED, Tokyo (JP)

(72) Inventors: Hiroyuki YAMAMOTO, Haibara-gun (JP); Kazuhide KUNO, Haibara-gun (JP)

(73) Assignee: ASAHI GLASS COMPANY, LIMITED, Tokyo (JP)

(21) Appl. No.: 13/721,428

(22) Filed: Dec. 20, 2012

Related U.S. Application Data
(63) Continuation of application No. PCT/JP2012/056647, filed on Mar. 15, 2012.

(30) Foreign Application Priority Data
Mar. 17, 2011 (JP) 2011-084039
Mar. 23, 2011 (JP) 2011-064618

(51) Int. Cl. H05K 5/00; C03C 3/091; C03C 4/02; C03C 3/085; C03C 3/087; C03C 3/095; C03C 3/04; C03C 3/083

(52) U.S. Cl. CPC H05K 5/0086; C03C 3/04; C03C 3/091; C03C 3/083; C03C 3/085; C03C 3/087; C03C 3/095; C03C 4/02
USPC 361/679.01; 428/34.4; 428/34.6

(57) ABSTRACT

There is provided a colored glass housing having characteristics suitable for a housing of an electronic device, that is, a light blocking property, high strength, and superior manufacturing cost. The colored glass housing includes glass whose absorbance at wavelength from 380 nm to 780 nm is 0.7 or more, suitably, whose absorption constant is 1 mm⁻¹ or more, and is provided on an exterior of the electronic device. In order to obtain the above glass, it is preferable that, as a coloring component in the glass, at least one component selected from a group consisting of oxides of Co, Mn, Fe, Ni, Cu, Cr, V, and Bi amounting to 0.1% to 7% in terms of molar percentage on an oxide basis.

### CROSS-REFERENCE TO RELATED APPLICATIONS

This application is a continuation of prior International Application No. PCT/JP2012/056647 filed on Mar. 15, 2012, which is based upon and claims the benefit of priority from Japanese Patent Applications Nos. 2011-084039 filed on Mar. 17, 2011 and 2011-064618 filed on Mar. 23, 2011; the entire contents of all of which are incorporated herein by reference.

### FIELD

Embodiments described herein relates to a colored glass housing used for electronic devices, for example, communication devices, information devices, and the like portably usable.

### BACKGROUND

For housings of electronic devices such as portable phones, a material is appropriately selected from materials such as resin and metal and is used in consideration of various factors such as decorativeness, scratch resistance, workability, and cost.

In recent years, an attempt has been made to use glass not conventionally used, as the material of the housings (JP-A 2009-061730 (KOKAI), JP-A 2005-129987 (KOKAI)). According to JP-A 2009-061730 (KOKAI), a housing main body is made of glass in an electronic device such as a portable phone, which makes it possible to exhibit a unique transparent decorative effect. Further, according to JP-A 2005-129987 (KOKAI), it is described that inner glass plates of a body case and a rear cover of a portable phone are not left transparent but are colored with a favorite color so as to become opaque.

### SUMMARY OF THE INVENTION

Electronic devices are provided with display devices such as liquid crystal panels on outer surfaces of the electronic devices. These display devices tend to have higher resolution and higher luminance, and accordingly backlights being light sources also tend to have higher luminance. Light from the light source is sometimes multiply reflected in the electronic device to reach a rear surface of a housing provided on an exterior of the electronic device, in addition to being radiated to the display device side. When metal is used as a material of the housing, there is no problem of the transmission of the light, but when the aforesaid glass having transparency is used, the light from the light source is liable to be transmitted through the housing and be recognized from the outside of the electronic device. Therefore, when the glass is used as the material of the housing, a light blocking means such as a coating film for imparting a light blocking property to the glass is formed on a rear surface of the glass.

In order to form the coating film having a sufficient light blocking property on the rear surface (electronic device side) of the glass in accordance with the increase in the luminance of the light source of the display device as described previously, it is necessary to form the coating film as a thick film or form a film composed of a plurality of layers, which will be a cause to increase cost due to many processes. Further, if the coating film is not uniformly formed, only a thin portion of the coating film transmits the light, which is liable to cause the disfigurement of the electronic device, such as that the housing is locally recognized as being bright. For example, when the housing is worked into a dented shape, it is necessary to form a coating film uniform on a whole of the dented surface side. But a process forming the coating film uniformly for a sufficient light blocking property is complicated and will be a cause of cost increase.

Further, in portably usable electronic devices such as portable phones, housings are required to have high strength in consideration of breakage due to a drop impact when in use and a contact scratch due to the long-term use.

Further, also functioning as a decorative member, the housing of the electronic device is required to be free of dents in a pock shape ascribable to bubbles in the glass and bubbles on the glass surface.

It is an object of the embodiments to provide a colored glass housing having characteristics suitable for a housing of an electronic device, such as a light blocking property.

The embodiments provide a colored glass housing including a glass with an absorption constant having a minimum value of 1 mm⁻¹ or more at wavelength from 380 nm to 780 nm, wherein the colored glass housing is configured to enclose an electronic device (hereinafter, sometimes referred to as the colored glass housing of the embodiments).

Further, the embodiments provides a colored glass housing including a plate made of glass, the plate having an absorbance of a minimum value of 0.7 or more at wavelength from 380 nm to 780 nm, wherein the colored glass housing is configured to enclose an electronic device. In order for the colored glass housing to satisfy this absorbance, it is preferable to use a plate made of glass with an absorption constant having 1 mm⁻¹ or more at wavelength from 380 nm to 780 nm and having a thickness of 5 mm or less.

Further, there is provided the colored glass housing of the embodiments, wherein the glass contains at least one component as a coloring component selected from a group consisting of oxides of Co, Mn, Fe, Ni, Cu, Cr, V, and Bi amounting to 0.1% to 7% in terms of molar percentage on an oxide basis.

Further, there is provided the colored glass housing of the embodiments, wherein the coloring component in the glass is composed of: 0.01% to 6% of Fe₂O₃; 0% to 6% of Co₃O₄; 0% to 6% of NiO; 0% to 6% of MnO; 0% to 6% of Cr₂O₃; and 0% to 6% of V₂O₅ in terms of molar percentage on an oxide basis.

Further, there is provided the colored glass housing of the embodiments, wherein the glass contains: 55% to 80% of SiO₂; 3% to 16% of Al₂O₃; 0% to 12% of B₂O₃; 5% to 16% of Na₂O; 0% to 4% of K₂O; 0% to 15% of MgO; 0% to 3% of CaO; 0% to 18% of ΣRO (where R represents Mg, Ca, Sr, Ba, and Zn); 0% to 1% of ZrO₂; and 0.1% to 7% of a coloring component having at least one component selected from the group consisting of oxides of Co, Mn, Fe, Ni, Cu, Cr, V, and Bi in terms of molar percentage on an oxide basis.

Further, there is provided the colored glass housing of the embodiments, wherein the glass contains: 60% to 80% of SiO₂; 3% to 15% of Al₂O₃; 5% to 15% of Na₂O; 0% to 4% of K₂O; 0% to 15% of MgO; 0% to 3% of CaO; 0% to 18% of ΣRO (where R represents Mg, Ca, Sr, Ba, and Zn); 0% to 1% of ZrO₂; 1.5% to 6% of Fe₂O₃; and 0.1% to 1% of Co₃O₄ in terms of molar percentage on an oxide basis.

Further, there is provided the colored glass housing of the embodiments, wherein the glass contains: 55% to 80% of SiO₂; 3% to 16% of Al₂O₃; 0% to 12% of B₂O₃; 5% to 16% of Na₂O; 0% to 4% of K₂O; 0% to 15% of MgO; 0% to 3% of CaO; 0% to 18% of ΣRO (where R represents Mg, Ca, Sr, Ba, and Zn); 0% to 1% of ZrO₂; 0.01% to 0.2% of Co₃O₄; 0.05% to 1% of NiO; and 0.01% to 3% of Fe₂O₃ in terms of molar percentage on an oxide basis.

Further, there is provided the colored glass housing of the embodiments, wherein the glass contains 0.005% to 2% of a color correction component having at least one component selected from a group consisting of oxides of Ti, Ce, Er, Nd, and Se.

Further, there is provided the colored glass housing of the embodiments, wherein a value of an absorption constant of the glass at 550 nm wavelength/an absorption constant of the glass at 600 nm wavelength and a value of an absorption constant of the glass at 450 nm wavelength/the absorption constant of the glass at 600 nm wavelength are both within a range of 0.7 to 1.2.

Further, there is provided the colored glass housing of the embodiments, wherein absolute values of variations ΔT (550/600) and ΔT (450/600) calculated from relative values of the absorption constants of the glass as expressed by the following expressions (1), (2) are 5% or less:

ΔT(550/600)(%)=[{A(550/600)−B(550/600)}/A(550/600)]×100 (1); and

ΔT(450/600)(%)=[{A(450/600)−B(450/600)}/A(450/600)]×100 (2),

where in the above expression (1), A(550/600) is a relative value of the absorption constant at 550 nm wavelength and the absorption constant at 600 nm wavelength, as calculated from a spectral transmittance curve of the glass after 100-hour irradiation with light of a 400 W high-pressure mercury lamp, and B(550/600) is a relative value of the absorption constant at 550 nm wavelength and the absorption constant at 600 nm wavelength, as calculated from a spectral transmittance curve of the glass before the irradiation with the light; in the above expression (2), A(450/600) is a relative value of the absorption constant at 450 nm wavelength and the absorption constant at 600 nm wavelength, as calculated from a spectral transmittance curve of the glass after the 100-hour irradiation with the light of the 400 W high-pressure mercury lamp, and B (450/600) is a relative value of the absorption constant at 450 nm wavelength and the absorption constant at 600 nm wavelength, as calculated from a spectral transmittance curve of the glass before the irradiation with the light.

Further, there is provided the colored glass housing of the embodiments, wherein the glass is crystallized glass.

Further, there is provided the colored glass housing of the embodiments, wherein the glass is chemically strengthened glass.

Further, there is provided the colored glass housing of the embodiments, wherein the glass has a compressive stress layer formed by chemical strengthening at a depth of 6 μm to 70 μm from a surface thereof.

Further, there is provided the colored glass housing of the embodiments, wherein the compressive stress layer is the depth of 30 μm or more, and a surface compressive stress of the glass is 550 MPa or more.

Further, there is provided the colored glass housing of the embodiments, wherein the electronic device is a portable electronic device.

The embodiments provides a portable electronic device including the colored glass housing described above, wherein the colored glass housing is configured to enclose the portable electronic device.

### DETAILED DESCRIPTION

Hereinafter, suitable embodiments of a colored glass housing according to the embodiments will be described.

The colored glass housing according to the embodiments is used as an exterior member of an electronic device. For example, on one side of an outer surface of a portable phone, a display device having a liquid crystal panel or organic EL and an operation device including buttons, or one in which the display device and the operation device are integrated such as a touch panel are (is) arranged, and a periphery thereof is surrounded by a rim member. On the opposite other surface, a panel is arranged. In a thickness portion of the electronic device between the one surface and the other surface, a frame member is provided. The rim member and the frame member or the panel and the frame member are sometimes integrally formed.

The colored glass housing is usable for any of the aforesaid rim member, panel, and frame member. Further, the colored glass housing may be in a flat plate shape, or may be in a dented shape or a bulging shape with the rim member and the frame member or the panel and the frame member being integrated.

A light source of the display device, provided in the electronic device, is one emitting white light such as a light-emitting diode, an organic EL, or a CCFL. Therefore, in order to prevent the white light from leaking to the outside of the electronic device via the colored glass housing, it is necessary to set the minimum value of absorbance of the colored glass housing at wavelength from 380 nm to 780 nm to 0.7 or more. The white light is recognized as white by compounding lights with a plurality of wavelengths in a visible range by using phosphors. Therefore, the minimum value of the absorbance at wavelength in the visible range is set to 0.7 or more, whereby the white light is absorbed by the sole glass without separately providing a light blocking means and the colored glass housing with a sufficient light blocking property is obtained. When the minimum value of the absorbance of the glass at wavelength from 380 nm to 780 nm is less than 0.7, a desired light blocking property cannot be obtained and the colored glass housing is liable to transmit the light. Further, when the colored glass housing is formed as the dented shape or the bulging shape, a portion with the smallest thickness is liable to transmit the light. When the colored glass housing has a small thickness, it is necessary to set the minimum value of the absorbance at the thin portion to 0.7 or more, and this absorbance is preferably 0.8 or more, more preferably 0.9 or more, and especially preferably 1.0 or more.

A method of calculating the absorbance in the embodiments is as follows. Both surfaces of a glass plate are mirror-polished and its thickness t is measured. Spectral transmittance T of this glass plate is measured (for example, an ultraviolet-visible/near-infrared spectrophotometer V-570 manufactured by JASCO Corporation is used). Then, the absorbance A is calculated by using a relational expression A=

By adjusting the thickness of the glass housing according to the absorption constant of the used glass at wavelength from 380 nm to 780 nm, it is possible to satisfy the aforesaid absorbance. Specifically, when glass whose absorption constant at wavelength from 380 nm to 780 nm is small is used, the thickness of the glass housing is made large, and when glass whose absorption constant is large is used, the thickness of the glass housing can be made small relatively. Incidentally, in the use as the glass housing, too large a thickness of the glass housing itself results in a heavy and large product, which is not preferable. The thickness of the glass housing provided on the exterior of the portable electronic device is preferably 5 mm or less, more preferably 3 mm or less, and especially preferably 1.5 mm or less.

The minimum value of the absorption constant of the used glass at wavelength from 380 nm to 780 nm is preferably large since the thickness of such a glass housing does not have to be unnecessarily large. The larger the absorption constant of the glass, the more easily the transmission of the light can be prevented even if the thickness of the glass housing is small. For example, the absorption constant of the glass is preferably 1 mm⁻¹ or more, more preferably 2 mm or more, still more preferably 3 mm⁻¹ or more, and especially preferably 4 mm⁻¹ or more.

A method of calculating the absorption constant in the embodiments is as follows. Both surfaces of a glass plate are mirror-polished and its thickness t is measured. Spectral transmittance T of this glass plate is measured (for example, an ultraviolet-visible/near-infrared spectrophotometer V-570 manufactured by JASCO Corporation is used). Then, an absorption constant β is calculated by using a relational expression T=10^{-βt}.

In order to set the minimum value of the absorbance of the glass of the colored glass housing at wavelength from 380 nm to 780 nm to 0.7 or more, it is preferable to use glass that contains at least one component, as a coloring component, selected from a group consisting of oxides of Co, Mn, Fe, Ni, Cu, Cr, V, and Bi amounting to 0.1% to 7% in terms of molar percentage on an oxide basis. Note that, when a plurality of coloring components are used, this content is a total amount of these. These coloring components are components imparting a desired color to the glass, and one having an action to absorb the aforesaid light with wavelengths in the visible range is used. When the content of the coloring component in the glass is less than 0.1%, even glass having a thickness large enough to be used for a housing cannot have a light blocking property, and the colored glass housing is liable to transmit the light. Preferably, its content is 0.5% or more, and typically 1% or more. Further, when the content of the coloring agent is over 7%, the glass is liable to become unstable. Preferably, its content is 6.5% or less, and typically 6% or less. The colored glass housing differs in thickness depending on its shape or the like, but the content of the coloring component in the glass is appropriately selected according to the thickness so as to prevent the glass from transmitting the light in the electronic device.

The coloring component in the glass is preferably contained in 0.01% to 6% of Fe₂O₃, 0% to 6% of Co₃O₄, 0% to 6% of NiO, 0% to 6% of MnO, 0% to 6% of CuO, 0% to 6% of CuO₂, 0% to 6% of Cr₂O₃, 0% to 6% of V₂O₅, and 0% to 6% of Bi₂O₃ in terms of molar percentage on the oxide basis. Further, with Fe₂O₃ being an essential component, appropriate components selected from Co₃O₄, NiO, MnO, Cr₂O₃, and V₂O₅ may be combined. When the content of Fe₂O₃ is less than 0.01%, a desired light blocking property may not be obtained. Further, when the content of Fe₂O₃ is over 6%, the glass is liable to become unstable. Further, when the contents of the other components each are over 6%, the glass is liable to become unstable.

In this specification, the content of the coloring component is an equivalent content when it is assumed that the components present in the glass exist as the recited oxides. For example, “contains 0.01% to 6% Fe₂O₃” means that the Fe content when Fe in the glass is assumed to all exist in the form of Fe₂O₃, that is the Fe₂O₃-equivalent content of Fe, is 0.01% to 6%. This also applied to a later-described color correction component.

Especially, in order for the minimum value of the absorption constant of the glass at wavelength from 380 nm to 780 nm to be 1 mm⁻¹ or more, it is preferable to combine a plurality of coloring components to have the absorption constant high on average in the range of aforesaid wavelength.

For example, when the coloring component in the glass contains the combination of 1.5% to 6% of Fe₂O₃ and 0.1% to 1% of Co₃O₄, it is possible for the glass to sufficiently absorb light in the visible range of wavelength from 380 nm to 780 nm and at the same time absorb the lights in the visible range on average. That is, when glass presenting a black color is intended to be obtained, the black color sometimes become brownish, bluish, or greenish black because an absorption property at a specific wavelength is low depending on the coloring component. On the other hand, the aforesaid coloring components make it possible to express a color tone called a coal-black. Besides the aforesaid combination of the coloring components, the combinations enabling to obtain such a property include, the combination of 0.01% to 4% of Fe₂O₃, 0.2% to 3% of Co₃O₄, and 1.5% to 6% of NiO, the combination of 1.5% to 6% of Fe₂O₃ and 0.1% to 1% of NiO, the combination of 0.01% to 4% of Fe₂O₃, 0.05% to 2% of Co₃O₄, 0.05% to 2% of NiO, and 0.05% to 2% of Cr₂O₃, the combination of 0.01% to 4% of Fe₂O₃, 0.05% to 2% of Co₃O₄, 0.05% to 2% of NiO, and 0.05% to 2% of MnO, and so on.

Further, combining the coloring components in the glass makes it possible for the glass to sufficiently absorb lights in the visible range of wavelength from 380 nm to 780 nm and at the same time transmit ultraviolet or infrared light with a specific wavelength. For example, when containing the aforesaid combination of Fe₂O₃, Co₃O₄, and NiO as the coloring component, the glass can transmit ultraviolet light with wavelength from 300 nm to 380 nm and infrared light. Further, when containing the aforesaid combination of Fe₂O₃ and Co₃O₄ as the coloring component, the glass can transmit infrared light with wavelength from 800 nm to 950 nm. An infrared communication device used for data communication of a portable phone and a portable game machine uses infrared light with wavelength from 800 nm to 950 nm. Therefore, by imparting an infrared-transmission property to the glass according to using the aforesaid combination of the coloring components, it is possible to use the glass without forming an opening portion for the infrared communication device in the colored glass housing.

For the purpose of adjusting a coloring degree of the glass, a color correction component containing at least one component selected from a group consisting of oxides of Ti, Ce, Er, Nd, and Se may be compounded. As the color correction component, concretely, TiO₂, Ce₂O₂, Er₂O₃, Nd₂O₃, and SeO₂ are preferably used.

When the metal oxide containing at least one kind selected from the group consisting of oxides of Ti, Ce, Er, Nd, and Se is compounded in the glass as the color correction component, the content of the metal oxide is preferably 0.005% to 2% in terms of molar percentage on an oxide basis. When total content of these components is 0.005% or more, it is possible to obtain glass capable of reducing a difference in the absorption property for light in wavelength of visible range and having a color tone of black called coal-black or a color tone of favorite gray without presenting a brown color or a blue color. Further, by setting the content of the aforesaid color correction component to 2% or less, it is possible to prevent the devitrification of the glass due to the instability of the glass. The total content of the aforesaid color correction components is more preferably 0.01% to 1.8%, and still more preferably 0.1% to 1.5%.

As the glass used in the colored glass housing of the embodiments, chemically strengthened glass (hereinafter, sometimes referred to as the glass of the first embodiment) or glass ceramics (hereinafter, sometimes referred to as the glass of the second embodiment) may be used so that the glass has high strength.

The chemically strengthened glass being the glass of the first embodiment will be described. As a method to increase the strength of glass, a method of forming a compressive stress layer on a glass surface has been generally known. As a method of forming the compressive stress layer on the glass surface, an air-cooling tempering method (physical tempering method) and a chemical strengthening method are typical. The air-cooling tempering method (physical tempering method) is a method to rapidly cool a glass plate surface heated up to the vicinity of a softening point by air cooling or the like. Further, the chemical strengthening method is a method in which alkali metal ions with a small ion radius (typically Li ions, Na ions) on the glass plate surface are exchanged with alkali ions with a larger ion radius (typically, Na ions or K ions for the Li ions, and K ions for the Na ions) by ion exchange at a temperature equal to or lower than a glass transition point.

In many cases, a thickness of the colored glass housing is usually 2 mm or less when it is assumed that the colored glass housing is a flat plate shape of a panel or the like, though depending on where it is used. When the air-cooling tempering method is applied for a glass plate thus having a small thickness, it is not easy to ensure a temperature difference between the surface and the interior, which makes it difficult to form the compressive stress layer. Therefore, it is not possible to obtain the intended high strength in the glass having undergone the strengthening.

Further, the air-cooling tempering involves a concern that planarity of the glass plate is impaired due to variation in cooling temperature. Especially in a thin glass plate, the concern that planarity is impaired is great, and there is a possibility that texture as a decorative member is impaired. In view of these points, the glass plate is preferably strengthened by the latter chemical strengthening method.

In the colored glass housing of the embodiments, when the chemical strengthening process is used to increase the strength, a depth of the surface compressive stress layer formed by the process is 6 μm to 70 μm. The reason is as follows.

In the manufacture of glass used for a housing, a polishing process is sometimes performed when the glass is in a flat-plate shape. In the polishing process of the glass, a grain size of a polishing abrasive used for polishing at its final stage is typically 2 μm to 6 μm. It is thought that by such an abrasive, microcracks with 5 μm at the maximum are finally formed on a glass surface. In order for the strength improving effect by the chemical strengthening to be effective, it is necessary that the surface compressive stress layer deeper than the microcracks occurred in the glass surface is formed on the glass surface, and therefore the depth of the surface compressive stress layer produced by the chemical strengthening is set to 6 μm or more. Further, a scratch whose depth exceeds the depth of the surface compressive stress layer, if formed when in use, leads to breakage of the glass. Therefore, the surface compressive stress layer is preferably deep, more preferably 10 μm or more, still more preferably 20 μm or more, and typically 30 μm or more.

In soda lime glass, by applying the aforesaid chemical strengthening method, it is possible to set a surface compressive stress formed on a glass surface to 550 MPa or more, but it is not easy to set the depth of the surface compressive stress layer to 30 μm or more. By chemically strengthening the glass used for the colored glass housing of the embodiments, in particular, the glass having the concrete composition described in the explanation of the later-described glass of the first embodiment, it is possible to set the depth of the surface compressive stress layer to 30 μm or more.

On the other hand, when the surface compressive stress layer is deep, an internal tensile stress becomes large, resulting in a large impact at the time of breakage. That is, it is known that, when the internal tensile stress is large, glass tends to become fine pieces when being broken, to scatter apart, leading to an increased danger. As a result of experiments by the inventors, it has been found out that, when the surface compressive stress layer has a depth more than 70 μm, glass with a thickness of 2 mm or less conspicuously scatters when being broken. Therefore, the depth of the surface compressive stress layer is set to 70 μm or less in the colored glass housing of the embodiments. When the glass is used for the colored glass housing, it can be thought that the depth of the surface compressive stress layer is made small in consideration of safety, for example, in the use as a panel or the like highly probable to suffer a contact scratch on its surface, though depending on an electronic device on whose exterior it is provided, and more preferably, the depth is 60 μm or less, still more preferably 50 μm or less, and typically 40 μm or less.

The glass used for the colored glass housing shown in this embodiment has the compressive stress layer formed on the glass surface by the chemical strengthening, and is preferably glass in which the surface compressive stress of this compressive stress layer is 550 MPa or more. Further, the surface compressive stress is more preferably 700 MPa or more. Further, typically, the surface compressive stress is 1200 MPa or less.

Hereinafter, the composition of the glass other than the coloring component in the glass of the first embodiment will be described by using the contents in terms of molar percentage unless otherwise mentioned.

An example of the glass used here is one having the composition containing, 55% to 80% of SiO₂, 3% to 16% of Al₂O₃, 0% to 12% of B₂O₃, 5% to 16% of Na₂O, 0% to 4% of K₂O, 0% to 15% of MgO, 0% to 3% of CaO, 0% to 18% of ΣRO (R represents Mg, Ca, Sr, Ba, and Zn), 0% to 1% of ZrO₂, and a 0.1% to 7% of coloring component (at least one component selected from a group consisting of oxides of Co, Mn, Fe, Ni, Cu, Cr, V, and Bi) in terms of molar percentage on an oxide basis.

SiO₂ is a component forming a skeletal structure of the glass and is essential. When its content is less than 55%, stability as the glass lowers, or weather resistance lowers. Preferably, its content is 60% or more, and more preferably 65% or more.

When the content of SiO₂ is over 80%, viscosity of the glass increases to greatly lower a melting property. Preferably, its content is 75% or less, and typically 70% or less.

Al₂O₃ is a component improving the weather resistance and chemical strengthenability of the glass and is essential. When its content is less than 3%, the weather resistance lowers. Its content is preferably 4% or more, and typically 5% or more.

When the content of Al₂O₃ is over 16%, the viscosity of the glass becomes high, which makes uniform melting difficult. Its content is preferably 14% or less, and typically 12% or less.

B₂O₃ is a component improving the weather resistance of the glass, and it can be contained as required, though not essential. When the content of B₂O₃, if it is contained, is less than 4%, a significant effect of improving the weather resistance may not be obtained. Its content is preferably 5% or more, and typically 6% or more.

When the content of B₂O₃ is over 12%, striae occur due to volatilization, which is liable to lower yields. Its content is preferably 11% or less, and typically 10% or less.

Na₂O is a component improving the melting property of the glass, and causes the surface compressive stress layer to be formed by ion exchange, and therefore is essential. When its content is less than 5%, the melting property worsens, or it is difficult to form a desired surface compressive stress layer by the ion exchange. Its content is preferably 7% or more, and typically 8% or more.

When the content of Na₂O is over 16%, the weather resistance lowers. Its content is preferably 15% or less, and typically 14% or less.

K₂O is not only a component improving the melting property of the glass but also has an action for increasing an ion exchange rate in the chemical strengthening, and therefore, is a component preferably contained, though not essential. When the content of K₂O, if it is contained, is less than 0.01%, a significant effect of improving the melting property may not be obtained or a significant effect of improving the ion exchange rate may not be obtained. Its content is typically 0.3% or more.

When the content of K₂O is over 4%, the weather resistance lowers. Its content is preferably 3% or less, and typically 2% or less.

MgO is a component improving the melting property of the glass, and can be contained as required, though not essential. When the content of MgO, if it is contained, is less than 3%, a significant effect of improving the melting property may not be obtained. Its content is typically 4% or more.

When the content of MgO is over 15%, the weather resistance lowers. Its content is preferably 13% or less, and typically 12% or less.

CaO is a component improving the melting property of the glass, and can be contained as required. When the content of CaO, if it contained, is less than 0.01%, a significant effect of improving the melting property cannot be obtained. Its content is typically 0.1% or more.

When the content of CaO is over 3%, the chemical strengthenability lowers. Its content is preferably 1% or less, typically 0.5% or less, and is preferably not substantially contained.

RO (R represents Mg, Ca, Sr, Ba, and Zn) is a component improving the melting property of the glass, and at least one kind or more can be contained as required, though it is not essential. In this case, when the total content ΣRO (R represents Mg, Ca, Sr, Ba, and Zn) of RO is less than 1%, the melting property is liable to lower. Its content is preferably 3% or more, and typically 5% or more.

When ΣRO (R represents Mg, Ca, Sr, Ba, and Zn) is over 18%, the weather resistance lowers. ΣRO is preferably 15% or less, more preferably 13% or less, and typically 11% or less.

ZrO₂ is a component increasing the ion exchange rate, and may be contained within a range of less than 1%, though not essential. When the content of ZrO₂ is over 1%, the melting property worsens and a case where it remains in the glass as an unmelted substance is liable to occur. Typically, ZrO₂ is not contained.

(SiO₂+Al₂O₃+B₂O₃)/(ΣR₂O+CaO+SrO+BaO+the coloring component) expresses a ratio of the total amount of network oxides forming a network of the glass and the total amount of main modifier oxides, and when this ratio is less than 4, a probability of breakage when an indentation is made after the chemical strengthening is liable to increase. The ratio is preferably 4.2 or more, and typically 4.4 or more. When this ratio is over 6, the viscosity of the glass increases and the melting property lowers. The ratio is preferably 5.5 or less, and more preferably 5 or less. Note that ΣR₂O represents the total amount of Na₂O, K₂O, and Li₂O.

Besides, the following components may be contained. SO₃ is a component acting as a clarifying agent and can be contained as required, though not essential. When the content of SO₃, if it is contained, is less than 0.005%, an expected clarifying action is not obtained. Its content is preferably 0.01% or more, and more preferably 0.02% or more. 0.03% or more is the most preferable. Further, when its content is over 0.5%, it serves as a source generating bubbles contrary to the intention, which is liable to slow down the melt-down of the glass or increase the number of bubbles. Its content is preferably 0.3% or less, and more preferably 0.2% or less. 0.1% or less is the most preferable.

SnO₂ is a component acting as a clarifying agent, and can be contained as required, though not essential. When the content of SnO₂, if it is contained, is less than 0.005%, an expected clarifying action cannot be obtained. Its content is preferably 0.01% or more, and more preferably 0.05% or more. Further, when its content is over 1%, it serves as a source generating bubbles contrary to the intention and is liable to slow down the melt-down of the glass or increase the number of bubbles. Its content is preferably 0.8% or less, and more preferably 0.5% or less. 0.3% or less is the most preferable.

TiO₂ is not only a component improving the weather resistance of the glass but also a color correction component adjusting a color tone of the glass, and can be contained as required, though not essential. When the content of TiO₂, if it is contained, is less than 0.005%, a significant effect of improving the weather resistance may not be obtained. Its content is preferably 0.01% or more, and typically 0.1% or more.

When the content of TiO₂ is over 1%, the glass becomes unstable and the devitrification is liable to occur. Its content is preferably 0.8% or less, and typically 0.6% or less.

Li₂O is a component for improving the melting property of the glass and can be contained as required, though not essential. When the content of Li₂O, if it is contained, is less than 1%, a significant effect of improving the melting property may not be obtained. Its content is preferably 3% or more, and typically 6% or more.

When the content of Li₂O is over 15%, the weather resistance is liable to lower. Its content is preferably 10% or less, and typically 5% or less.

SrO is a component for improving the melting property of the glass, and can be contained as required, though not essential. When the content of SrO, if it is contained, is less than 1%, a significant effect of improving the melting property may not be obtained. Its content is preferably 3% or more, and typically 6% or more.

When the content of SrO is over 15%, the weather resistance and the chemical strengthenability are liable to lower. Its content is preferably 12% or less, and typically 9% or less.

BaO is a component for improving the melting property of the glass, and can be contained as required, though not essential. When the content of BaO, if it is contained, is less than 1%, a significant effect of improving the melting property may not be obtained. Its content is preferably 3% or more, and typically 6% or more.

When the content of BaO is over 15%, the weather resistance and the chemical strengthenability are liable to lower. Its content is preferably 12% or less, and typically 9% or less.

ZnO is a component for improving the melting property of the glass, and can be contained as required, though not essential. When the content of ZnO, if it is contained, is less than 1%, a significant effect of improving the melting property may not be obtained. Its content is preferably 3% or more, and typically 6% or more.

When the content of ZnO is over 15%, the weather resistance is liable to lower. Its content is preferably 12% or less, and typically 9% or less.

As a clarifying agent of the glass, Sb₂O₃, Cl, F, and other components may be contained within a range not impairing the object of the present invention. When such components are contained, the total content of these components is preferably 1% or less, and typically 0.5% or less.

When Co₃O₄ and Fe₂O₃ coexist, a bubble eliminating effect is exhibited when the glass melts, and therefore, they are preferably selected as coloring components. Specifically, O₂ bubbles released when trivalent iron becomes bivalent iron in a high-temperature state are absorbed when cobalt is oxidized, and as a result, the O₂ bubbles are reduced, and the bubble eliminating effect is obtained.

Further, Co₃O₄ is a component increasing a clarifying action when it coexists with SO₃. Specifically, when sodium sulfate (Na₂SO₄) is used as a clarifying agent, the progress of the reaction of SO₃→SO₂+½O₂ improves deaeration, and therefore, an oxygen partial pressure in the glass is preferably low. By adding cobalt in glass containing iron, the release of oxygen due to the reduction of iron is suppressed by the oxidation of cobalt, so that the decomposition of SO₃ is promoted, which makes it possible to fabricate the glass with little bubble defects.

Further, glass containing a relatively large amount of alkali metal for the purpose of the chemical strengthening has increased basicity, so that SO₃ is not easily decomposed, and the clarifying effect lowers. In chemically strengthened glass whose SO₃ is not easily decomposed and which contains iron as a coloring agent, cobalt is especially effective for promoting the decomposition of SO₃.

In order to make such a clarifying action exhibited, the content of Co₃O₄ is set to 0.1% or more, preferably 0.2% or more, and typically 0.3% or more. When its content is over 1%, the glass becomes unstable and the devitrification is liable to occur. Its content is preferably 0.8% or less, and more preferably 0.6% or less.

When a molar ratio of Co₃O₄ and Fe₂O₃ (Co₃O₄/Fe₂O₃ ratio) is less than 0.01, the aforesaid effect may not be obtained. The molar ratio is preferably 0.05 or more, and typically 0.1 or more. When the Co₃O₄/Fe₂O₃ ratio is over 0.5, it serves as a source generating bubbles contrary to the intention, which is liable to slow down the melt-down of the glass and increase the number of bubbles, and therefore, a measure such as the additional use of a clarifying agent is required. The molar ratio is preferably 0.3 or less, and more preferably 0.2 or less.

A method of manufacturing the glass of the first embodiment is not particularly limited, but for example, it is manufactured in such a manner that appropriate amounts of various raw materials are compounded, and after the resultant is melted by being heated to about 1500° C. to 1600° C., it is made uniform by deaeration, agitation, or the like, is molded into a plate shape or the like by a known down-draw method, pressing method, roll-out method, or the like, or is molded into a block shape by casting, and after annealing, is cut to a desired size, and is subjected to polishing as required.

Further, among the above-described compositions of the glass of the first embodiment, in order for the colored glass to present a black color, the glass preferably contains, 60% to 80% of SiO₂, 3% to 15% of Al₂O₃, 5% to 15% of Na₂O, 0% to 4% of K₂O, 0% to 15% of MgO, 0% to 3% of CaO, 0% to 18% of ΣRO (R represents Mg, Ca, Sr, Ba, and Zn), 0% to 1% of ZrO₂, 1.5% to 6% of Fe₂O₃, and 0.1% to 1% of Co₃O₄ in terms of molar percentage on an oxide basis.

SiO₂ is a component forming the skeletal structure of the glass and is essential. When its content is less than 60%, the stability as the glass lowers, or the weather resistance lowers. Preferably, its content is 61% or more, and more preferably 65% or more. When the content of SiO₂ is over 80%, the viscosity of the glass increases to greatly lower the melting property. Preferably, its content is 75% or less, and typically 70% or less.

Al₂O₃ is a component improving the weather resistance and the chemical strengthenability of the glass and is essential. When its content is less than 3%, the weather resistance lowers. Its content is preferably 4% or more, and typically 5% or more. When the content of Al₂O₃ is over 15%, the viscosity of the glass becomes high, which makes uniform melting difficult. Its content is preferably 14% or less, and typically 12% or less.

Na₂O is a component improving the melting property of the glass, and causes the surface compressive stress layer to be formed by the ion exchange, and therefore is essential. When its content is less than 5%, the melting property worsens, or it is difficult to form a desired surface compressive stress layer by the ion exchange. Its content is preferably 7% or more, and typically 8% or more. When the content of Na₂O is over 15%, the weather resistance lowers. Its content is preferably 15% or less, and typically 14% or less.

K₂O is not only a component improving the melting property but also has an action for increasing the ion exchange rate in the chemical strengthening, and therefore, is a component preferably contained, though not essential. When the content of K₂O, if it is contained, is less than 0.01%, a significant effect of improving the melting property may not be obtained or a significant effect of improving the ion exchange rate may not be obtained. Its content is typically 0.3% or more. When the content of K₂O is over 4%, the weather resistance lowers. Its content is preferably 3% or less, and typically 2% or less.

MgO is a component improving the melting property, and can be contained as required, though not essential. When the content of MgO, if it is contained, is less than 3%, a significant effect of improving the melting property may not be obtained. Its content is typically 4% or more. When the content of MgO is over 15%, the weather resistance lowers. Its content is preferably 13% or less, and typically 12% or less.

CaO is a component improving the melting property of the glass, and can be contained as required. When the content of CaO, if it is contained, is less than 0.01%, a significant effect of improving the melting property cannot be obtained. Its content is typically 0.1% or more. When the content of CaO is over 3%, the chemical strengthenability lowers. Its content is preferably 1% or less, typically 0.5% or less, and is preferably not substantially contained.

RO (R represents Mg, Ca, Sr, Ba, and Zn) is a component improving the melting property, and at least one kind or more can be contained as required, though it is not essential. In this case, when the total content ΣRO (R represents Mg, Ca, Sr, Ba, and Zn) of RO is less than 1%, the melting property is liable to lower. ΣRO is preferably 3% or more, and typically 5% or more. When ΣRO (R represents Mg, Ca, Sr, Ba, and Zn) is over 18%, the weather resistance lowers. ΣRO is preferably 15% or less, more preferably 13% or less, and typically 11% or less. Note that ΣRO represents the total amount of all the RO components.

ZrO₂ is a component increasing the ion exchange rate, and may be contained within a range of less than 1%, though not essential. When the content of ZrO₂ is over 1%, the melting property worsens and a case where it remains in the glass as an unmelted substance is liable to occur. Typically, ZrO₂ is not contained.

Fe₂O₃ is an essential component for imparting a deep color to the glass. When the total content of iron expressed in terms of Fe₂O₃ is less than 1.5%, glass having the desired black color cannot be obtained. Its content is preferably 2% or more, and more preferably 3% or more. When the content of Fe₂O₃ is over 6%, the glass becomes unstable and the devitrification is liable to occur. Its content is preferably 5% or less, and more preferably 4% or less.

Among all the irons, a ratio of the Fe₂O₃-equivalent content of bivalent iron (iron redox) is preferably 10% to 50%, in particular, 15% to 40%. 20% to 30% is the most preferable. When the iron redox is less than 10%, the decomposition of SO₃, if it is contained, does not progress, and an expected clarifying effect may not be obtained. When the iron redox is higher than 50%, the decomposition of SO₃ progresses too much before the clarification and an expected clarifying effect may not be obtained, or it becomes a source generating bubbles and the number of bubbles is liable to increase.

In this specification, the content of all the irons expressed in terms of Fe₂O₃ is described as the content of Fe₂O₃. As for the iron redox, a ratio of bivalent iron converted to Fe₂O₃ in all the irons converted to Fe₂O₃ by Mossbauer spectroscopy can be shown in terms of %. Concretely, evaluation is made by a transmission optical system in which a radiation source (⁵⁷Co), a glass sample (a glass flat plate with a thickness of 3 mm to 7 mm cut from the aforesaid glass block, ground, and mirror-polished), and a detector (45431 manufactured by LND, Inc.) are disposed on a straight line. The radiation source is moved relatively in an axial direction of the optical system to cause an energy change of a γ ray due to a Doppler effect. Then, by using a Mossbauer absorption spectrum obtained at room temperature, ratios of bivalent Fe and trivalent Fe are calculated, and the ratio of the bivalent Fe is defined as the iron redox.

Co₃O₄ is not only a coloring component but also exhibits a bubble eliminating effect when coexisting with iron, and therefore, is a component preferably used in this embodiment specifically, O₂ bubbles released when trivalent iron becomes bivalent iron in a high-temperature state are absorbed when cobalt is oxidized, and as a result, the O₂ bubbles are reduced, and the bubble eliminating effect is obtained.

Further, Co₃O₄ is a component increasing a clarifying action when it coexists with SO₃. Specifically, when sodium sulfate (Na₂SO₄) is used as a clarifying agent, the progress of the reaction of SO₃→SO₂+½O₂ improves the deaeration from the glass, and therefore, an oxygen partial pressure in the glass is preferably low. By adding cobalt in glass containing iron, the release of oxygen due to the reduction of iron can be suppressed by the oxidation of cobalt, so that the decomposition of SO₃ is promoted. This makes it possible to fabricate the glass with little bubble defects.

Further, glass containing a relatively large amount of alkali metal for the purpose of the chemical strengthening has increased basicity, so that SO₃ is not easily decomposed, and the clarifying effect lowers. In chemically strengthened glass whose SO₃ is thus not easily decomposed and which contains iron, the addition of cobalt is especially effective for promoting the bubble eliminating effect because it promotes the decomposition of SO₃.

In order to make such a clarifying action exhibited, the content of Co₃O₄ is set to 0.1% or more, preferably 0.2% or more, and typically 0.3% or more. When its content is over 1%, the glass becomes unstable and the devitrification is liable to occur. Its content is preferably 0.8% or less, and more preferably 0.6% or less.

When a molar ratio of Co₃O₄ and Fe₂O₃ (Co₃O₄/Fe₂O₃ ratio) is less than 0.01, the aforesaid bubble eliminating effect may not be obtained. The molar ratio is preferably 0.05 or more, and typically 0.1 or more. When the Co₃O₄/Fe₂O₃ ratio is over 0.5, it serves as a source generating bubbles contrary to the intention, which is liable to slow down the melt-down of the glass and increase the number of bubbles, and therefore, a measure such as the additional use of a clarifying agent is required. The molar ratio is preferably 0.3 or less, and more preferably 0.2 or less.

NiO is a coloring component for imparting a desired black color to the glass and is a component preferably used. When the content of NiO, if it is contained, is less than 0.05%, an effect as the coloring component cannot be sufficiently obtained. Its content is preferably 0.1% or more, and more preferably 0.2% or more. When the content of NiO is over 6%, brightness of the color tone of the glass becomes too high, and the desired black color tone cannot be obtained. Further, the glass becomes unstable and the devitrification is liable to occur. Its content is preferably 5% or less, and more preferably 4% or less.

(SiO₂+Al₂O₃+B₂O₃)/(ΣR₂O+CaO+SrO+BaO+Fe₂O₃+Co₃O₄) expresses a ratio of the total amount of network oxides forming a network of the glass and the total amount of main modifier oxides, and when this ratio is less than 3, a probability of breakage when an indentation is made after the chemical strengthening is liable to increase. The ratio is preferably 3.6 or more, and typically 4 or more. When this ratio is over 6, the viscosity of the glass increases and the melting property lowers. The ratio is preferably 5.5 or less, and more preferably 5 or less. Note that ΣR₂O represents the total amount of Na₂O, K₂O, and Li₂O.

SO₃ is a component acting as a clarifying agent and can be contained as required, though not essential. When the content of SO₃, if it is contained, is less than 0.005%, an expected clarifying action is not obtained. Its content is preferably 0.01% or more, and more preferably 0.02% or more. 0.03% or more is the most preferable. Further, when its content is over 0.5%, it serves as a source generating bubbles contrary to the intention, which is liable to slow down the melt-down of the glass or increase the number of bubbles. Its content is preferably 0.3% or less, and more preferably 0.2% or less. 0.1% or less is the most preferable.

SnO₂ is a component acting as a clarifying agent, and can be contained as required, though not essential. When the content of SnO₂, if it is contained, is less than 0.005%, an expected clarifying action cannot be obtained. Its content is preferably 0.01% or more, and more preferably 0.05% or more. Further, when its content is over 1%, it serves as a source generating bubbles contrary to the intention, which is liable to slow down the melt-down of the glass and increase the number of bubbles. Its content is preferably 0.8% or less, and more preferably 0.5% or less. 0.3% or less is the most preferable.

TiO₂ is not only a component improving the weather resistance but also a color correction component adjusting the color tone of the glass, and can be contained as required, though not essential. When the content of TiO₂, if it is contained, is less than 0.005%, a significant effect of improving the weather resistance may not be obtained. In addition, the color correction effect cannot be sufficiently obtained, so that it may not be possible to sufficiently prevent blackish glass from having a color tone of, for example, bluish black or brownish black. Its content is preferably 0.01% or more, and typically 0.1% or more. When the content of TiO₂ is over 1%, the glass becomes unstable and the devitrification is liable to occur. Its content is preferably 0.8% or less, and typically 0.6% or less.

Li₂O is a component for improving the melting property and can be contained as required, though not essential. When the content of Li₂O, if it is contained, is less than 1%, it may not be possible to obtain a significant effect of improving the melting property. Its content is preferably 3% or more, and typically 6% or more. When the content of Li₂O is over 15%, the weather resistance is liable to lower. Its content is preferably 10% or less, and typically 5% or less.

SrO is a component for improving the melting property, and can be contained as required, though not essential. When the content of SrO, if it is contained, is less than 1%, a significant effect of improving the melting property may not be obtained. Its content is preferably 3% or more, and typically 6% or more. When the content of SrO is over 15%, the weather resistance and the chemical strengthenability are liable to lower. Its content is preferably 12% or less, and typically 9% or less.

BaO is a component for improving the melting property, and can be contained as required, though not essential. When the content of BaO, if it is contained, is less than 1%, a significant effect of improving the melting property may not be obtained. Its content is preferably 3% or more, and typically 6% or more. When the content of BaO is over 15%, the weather resistance and the chemical strengthenability are liable to lower. Its content is preferably 12% or less, and typically 9% or less.

ZnO is a component for improving the melting property, and can be contained as required, though not essential. When the content of ZnO, if it is contained, is less than 1%, a significant effect of improving the melting property may not be obtained. Its content is preferably 3% or more, and typically 6% or more. When the content of ZnO is over 15%, the weather resistance is liable to lower. Its content is preferably 12% or less, and typically 9% or less.

Further, for the purpose of adjusting a coloring degree of the glass, a color correction component containing at least one component selected from a group consisting of oxides of Ti, Cu, Ce, Er, Nd, Mn, Cr, V, and Bi may be compounded. As this color correction component, concretely, TiO₂, CuO, Cu₂O, Ce₂O₂, Er₂O₃, Nd₂O₃, MnO, MnO₂, Cr₂O₃, V₂O₅, and Bi₂O₃ are suitably used, for instance. Note that the oxides of Cu, Mn, Cr, V, and Bi being the coloring components also function as the color correction components.

When the metal oxide containing at least one kind selected from a group consisting of oxides of Ti, Ce, Er, Nd, and Se is compounded as the color correction component, the content thereof is preferably 0.005% to 2%. When the total content of these components is 0.005% or more, it is possible to reduce a difference in an absorption property for light in the visible wavelength range, so that it is possible to obtain glass not presenting a brown color or a blue color but having a stable color tone such as what is called coal black or gray. Further, by setting the content of the aforesaid color correction components to 2% or less, it is possible to prevent the glass from becoming unstable and the devitrification from occurring. The total content of the aforesaid color correction components is more preferably 0.01% to 1.8%, and still more preferably 0.05% to 1.5%.

Further, among the aforesaid glass compositions, in order for the colored glass to have a grayish color tone, the glass preferably contains 55% to 80% of SiO₂, 3% to 16% of Al₂O₃, 0% to 12% of B₂O₃, 5% to 16% of Na₂O, 0% to 4% of K₂O, 0% to 15% of MgO, 0% to 3% of CaO, 0% to 18% of ΣRO (R represents Mg, Ca, Sr, Ba, and Zn), 0% to 1% of ZrO₂, 0.01% to 0.2% of Co₃O₄, 0.05% to 1% of NiO, and 0.01% to 3% of Fe₂O₃.

SiO₂ is a component forming the skeletal structure of the glass and is essential. When its content is less than 55%, the stability as the glass lowers, or the weather resistance lowers. Preferably, its content is 61% or more, and more preferably 65% or more. When the content of SiO₂ is over 80%, the viscosity of the glass increases to greatly lower the melting property. Preferably, its content is 75% or less, and typically 70% or less.

Al₂O₃ is a component improving the weather resistance and the chemical strengthenability of the glass and is essential. When its content is less than 3%, the weather resistance lowers. Its content is preferably 4% or more, and typically 5% or more. When the content of Al₂O₃ is over 16%, the viscosity of the glass becomes high, which makes uniform melting difficult. Its content is preferably 14% or less, and typically 12% or less.

B₂O₃ is a component improving the weather resistance, and is a component preferably contained, though not essential. When the content of B₂O₃, if it is contained, is less than 4%, a significant effect of improving the weather resistance may not be obtained. Its content is preferably 5% or more, and typically 6% or more. When the content of B₂O₃ is over 12%, striae occur due to volatilization, which is liable to lower yields. Its content is preferably 11% or less, and typically 10% or less.

Na₂O is a component improving the melting property of the glass, and causes the surface compressive stress layer to be formed by the ion exchange, and therefore is essential. When its content is less than 5%, the melting property worsens, or it is difficult to form a desired surface compressive stress layer by the ion exchange. Its content is preferably 7% or more, and typically 8% or more. When the content of Na₂O is over 16%, the weather resistance lowers. Its content is preferably 15% or less, and typically 14% or less.

K₂O is not only a component improving the melting property but also has an action for increasing the ion exchange rate in the chemical strengthening, and therefore, is a component preferably contained, though not essential. When the content of K₂O, if it is contained, is less than 0.01%, a significant effect of improving the melting property may not be obtained or a significant effect of improving the ion exchange rate may not be obtained. Its content is typically 0.3% or more. When the content of K₂O is over 4%, the weather resistance lowers. Its content is preferably 3% or less, and typically 2% or less.

MgO is a component improving the melting property, and can be contained as required, though not essential. When the content of MgO, if it is contained, is less than 3%, a significant effect of improving the melting property may not be obtained. Its content is typically 4% or more. When the content of MgO is over 15%, the weather resistance lowers. Its content is preferably 13% or less, and typically 12% or less.

CaO is a component improving the melting property, and can be contained as required. When the content of CaO, if it is contained, is less than 0.01%, a significant effect of improving the melting property cannot be obtained. Its content is typically 0.1% or more. When the content of CaO is over 3%, the chemical strengthenability lowers. Its content is preferably 1% or less, typically 0.5% or less, and is preferably not substantially contained.

RO (R represents Mg, Ca, Sr, Ba, and Zn) is a component improving the melting property, and at least one kind or more can be contained as required, though it is not essential. In this case, when the total content ΣRO (R represents Mg, Ca, Sr, Ba, and Zn) of RO is less than 1%, the melting property is liable to lower. ΣRO is preferably 3% or more, and typically 5% or more. When ΣRO (R represents Mg, Ca, Sr, Ba, and Zn) is over 18%, the weather resistance lowers. It is preferably 15% or less, more preferably 13% or less, and typically 11% or less. Note that ΣRO represents the total amount of all the RO components.

ZrO₂ is a component increasing the ion exchange rate, and may be contained within a range of less than 1%, though not essential. When the content of ZrO₂ is over 1%, the melting property worsens and a case where it remains in the glass as an unmelted substance may occur. Typically, ZrO₂ is not contained.

Fe₂O₃ is an essential component for imparting a deep color to the glass. When the total content of iron expressed in terms of Fe₂O₃ is less than 0.01%, glass having a desired gray color cannot be obtained. The total iron content is preferably 0.02% or more, and more preferably 0.03% or more. When the content of Fe₂O₃ is over 3%, the color tone of the glass becomes too dark, and a desired gray color tone cannot be obtained. Further, the glass becomes unstable and the devitrification is liable to occur. Its content is preferably 2.5% or less, and more preferably 2.2% or less.

Among all the irons, a ratio of the Fe₂O₃-equivalent content of bivalent iron (iron redox) is preferably 10% to 50%, in particular, 15% to 40%. 20% to 30% is the most preferable. When the iron redox is lower than 10%, the decomposition of SO₃, if it is contained, does not progress, and an expected clarifying effect may not be obtained. When the ratio is higher than 50%, the decomposition of SO₃ progresses too much before the clarification and an expected clarifying effect may not be obtained, or it becomes a source generating bubbles and the number of bubbles is liable to increase.

In this specification, the Fe₂O₃-equivalent content of all the irons is described as the content of Fe₂O₃. As for the iron redox, a ratio of bivalent iron converted to Fe₂O₃ in all the irons converted to Fe₂O₃ by Mossbauer spectroscopy can be shown in terms of %. Concretely, evaluation is made by a transmission optical system in which a radiation source (⁵⁷Co), a glass sample (a glass flat plate with a thickness of 3 mm to 7 mm cut from the aforesaid glass block, ground, and mirror-polished), and a detector (45431 manufactured by LND, Inc.) are disposed on a straight line. The radiation source is moved relatively in an axial direction of the optical system to cause an energy change of a γ ray due to a Doppler effect. Then, by using a Mossbauer absorption spectrum obtained at room temperature, ratios of bivalent Fe and trivalent Fe are calculated, and the ratio of the bivalent Fe is defined as the iron redox.

Co₃O₄ is not only a coloring component for imparting a deep color to the glass but also exhibits a bubble eliminating effect when coexisting with iron, and therefore, is essential. Specifically, O₂ bubbles released when trivalent iron becomes bivalent iron in a high-temperature state are absorbed when cobalt is oxidized, and as a result, the O₂ bubbles are reduced, and the bubble eliminating effect is obtained.

Further, Co₃O₄ is a component increasing a clarifying action when it coexists with SO₃. Specifically, when sodium sulfate (Na₂SO₄) is used as a clarifying agent, the progress of the reaction of SO₃→SO₂+½O₂ improves the deaeration from the glass, and therefore, an oxygen partial pressure in the glass is preferably low. By adding cobalt in glass containing iron, the release of oxygen due to the reduction of iron is suppressed by the oxidation of cobalt, so that the decomposition of SO₃ is promoted. This makes it possible to fabricate the glass with little bubble defects.

Further, glass containing a relatively large amount of alkali metal for the purpose of the chemical strengthening has increased basicity, so that SO₃ is not easily decomposed, and the clarifying effect lowers. In chemically strengthened glass whose SO₃ is not thus easily decomposed and which contains iron, cobalt is especially effective for promoting the bubble eliminating effect because it promotes the decomposition of SO₃.

In order to make such a clarifying action exhibited, the content of Co₃O₄ is set to 0.01% or more, preferably 0.02% or more, and typically 0.03% or more. When its content is over 0.2%, the glass becomes unstable and the devitrification is liable to occur. Its content is preferably 0.18% or less, and more preferably 0.15% or less.

NiO is a coloring component for imparting a desired gray color tone to the glass and is an essential component. When the content of NiO is less than 0.05%, a desired gray color tone cannot be obtained in the glass. Its content is preferably 0.1% or more, and more preferably 0.2% or more. When the content of NiO is over 1%, the brightness of the color tone of the glass becomes too high, and the desired gray color tone cannot be obtained. Further, the glass becomes unstable and the devitrification is liable to occur. Its content is preferably 0.9% or less, and more preferably 0.8% or less.

When a molar ratio of Co₃O₄ and Fe₂O₃ (Co₃O₄/Fe₂O₃ ratio) is less than 0.01, the aforesaid bubble eliminating effect may not be obtained. The molar ratio is preferably 0.05 or more, and typically 0.1 or more. When the Co₃O₄/Fe₂O₃ ratio is over 0.5, it serves as a source generating bubbles contrary to the intention, which is liable to slow down the melt-down of the glass and increase the number of bubbles, and therefore, a measure such as the additional use of a clarifying agent is required. Further, the desired gray color tone cannot be obtained as the whole glass. The molar ratio is preferably 0.3 or less, and more preferably 0.2 or less.

(SiO₂+Al₂O₃+B₂O₃)/(ΣR₂O+CaO+SrO+BaO+NiO+Fe₂O₃+Co₃O₄) expresses a ratio of the total amount of network oxides forming a network of the glass and the total amount of main modifier oxides, and when this ratio is less than 3, a probability of breakage when an indentation is made after the chemical strengthening is liable to increase. The ratio is preferably 3.6 or more, and typically 4 or more. When this ratio is over 6, the viscosity of the glass increases, so that the melting property is liable to lower. The ratio is preferably 5.5 or less, and more preferably 5 or less. Note that ΣR₂O represents the total amount of Na₂O, K₂O, and Li₂O.

SO₃ is a component acting as a clarifying agent and can be contained as required, though not essential. When the content of SO₃, if it is contained, is less than 0.005%, an expected clarifying action cannot be obtained. Its content is preferably 0.01% or more, and more preferably 0.02% or more. 0.03% or more is the most preferable. Further, when its content is over 0.5%, it serves as a source generating bubbles contrary to the intention, which is liable to slow down the melt-down of the glass or increase the number of bubbles. Its content is preferably 0.3% or less, and more preferably 0.2% or less. 0.1% or less is the most preferable.

SnO₂ is a component acting as a clarifying agent, and can be contained as required, though not essential. When the content of SnO₂, if it is contained, is less than 0.005%, an expected clarifying action cannot be obtained. Its content is preferably 0.01% or more, and more preferably 0.05% or more. Further, when its content is over 1%, it serves as a source generating bubbles contrary to the intention, which is liable to slow down the melt-down of the glass and increase the number of bubbles. Its content is preferably 0.8% or less, and more preferably 0.5% or less. 0.3% or less is the most preferable.

TiO₂ is a component not only improving the weather resistance but also a color correction component adjusting the color tone of the glass, and can be contained as required, though not essential. When the content of TiO₂, if it is contained, is less than 0.1%, a sufficient color correction effect cannot be obtained, so that it may not be possible to sufficiently prevent grayish glass from having a color tone of, for example, bluish gray or brownish gray. Further, a significant effect of improving the weather resistance may not be obtained. Its content is preferably 0.15% or more, and typically 0.2% or more. When the content of TiO₂ is over 1%, the glass becomes unstable and the devitrification is liable to occur. Its content is preferably 0.8% or less, and typically 0.6% or less.

CuO is a color correction component adjusting the color tone of the glass, and can be contained as required, though not essential. When the content of CuO, if it is contained, is less than 0.1%, a significant effect of adjusting the color tone may not be obtained. Its content is preferably 0.2% or more, and typically 0.5% or more. When the content of CuO is over 3%, the glass becomes unstable and the devitrification is liable to occur. Its content is preferably 2.5% or less, and typically 2% or less.

Li₂O is a component for improving the melting property and can be contained as required, though not essential. When the content of Li₂O, if it is contained, is less than 1%, a significant effect of improving the melting property may not be obtained. Its content is preferably 3% or more, and typically 6% or more. When the content of Li₂O is over 15%, the weather resistance is liable to lower. Its content is preferably 10% or less, and typically 5% or less.

SrO is a component for improving the melting property, and can be contained as required, though not essential. When the content of SrO, if it is contained, is less than 1%, a significant effect of improving the melting property may not be obtained. Its content is preferably 3% or more, and typically 6% or more. When the content of SrO is over 15%, the weather resistance and the chemical strengthenability are liable to lower. Its content is preferably 12% or less, and typically 9% or less.

BaO is a component for improving the melting property, and can be contained as required, though not essential. When the content of BaO, if it is contained, is less than 1%, a significant effect of improving the melting property may not be obtained. Its content is preferably 3% or more, and typically 6% or more. When the content of BaO is over 15%, the weather resistance and the chemical strengthenability are liable to lower. Its content is preferably 12% or less, and typically 9% or less.

ZnO is a component for improving the melting property, and can be contained as required, though not essential. When the content of ZnO, if it is contained, is less than 1%, a significant effect of improving the melting property may not be obtained. Its content is preferably 3% or more, and typically 6% or more. When the content of ZnO is over 15%, the weather resistance is liable to lower. Its content is preferably 12% or less, and typically 9% or less.

CeO₂, Er₂O₃, Nd₂O₃, MnO₂, and SeO₂ are color correction components adjusting the color tone of the glass, and can be contained as required, though not essential. When these color correction components are contained, if the content of each of them is less than 0.005%, it is not possible to sufficiently obtain the effect of adjusting the color tone, that is, the effect of the color correction, and it may not be possible to fully prevent the glass from presenting the color tone of, for example, bluish gray or brownish gray. The content of each of these color correction components is preferably 0.05% or more, and typically 0.1% or more. When the content of each of these color correction components is over 2%, the glass becomes unstable and the devitrification is liable to occur. Its content is typically 1.5% or less.

When the aforesaid color correction components are used, an amount and kind thereof can be appropriately selected according to the composition serving as the base of each glass.

As the aforesaid color correction components, the total content of TiO₂, CeO₂, Er₂O₃, Nd₂O₃, MnO₂, and SeO₂ is preferably 0.005% to 3%, and the total content of CeO₂, Er₂O₃, Nd₂O₃, MnO₂, and SeO₂ is preferably 0.005% to 2%.

By setting the content of the color correction components within the aforesaid ranges, it is possible to obtain a sufficient color correction effect and obtain stable glass.

In the foregoing, the glass composition is concretely described, and the glass having such a composition is chemically strengthened. A method of the chemical strengthening is not particularly limited, provided that it can ion-exchange Na₂O of the glass surface layer and K₂O in a molten salt. An example of the method is a method in which the glass is immersed in a heated potassium nitrate (KNO₃) molten salt.

A condition for forming a chemically strengthened layer having a desired surface compressive stress (surface compressive stress layer) on the glass depends on the thickness of the glass, but typically, the glass is immersed in a 400° C. to 550° C. KNO₃ molten salt for two hours to twenty hours. Further, this KNO₃ molten salt may be, for example, one containing about 5% NaNO₃ or less, besides KNO₃.

Next, the glass ceramics being the glass of the second embodiment will be described. As for the glass ceramics, molten glass is cooled to be molded into a desired shape, and the resultant crystalline glass is heat-treated, whereby crystals are precipitated, and the glass ceramics is high in mechanical strength and hardness and has a characteristic of being excellent in heat resistance and electrical property.

Some glass ceramics presents a white color (opaque) and some is transparent depending on the size of crystal grains. When the crystal grains are larger than a visible wavelength, light transmitted by the glass scatters due to the crystals to present a white color. By making the aforesaid coloring components contained in the white glass ceramics, it is possible to obtain glass high in strength and a light blocking property. Further, when the crystal grains are sufficiently smaller than the visible wavelength, the glass becomes transparent. By making the aforesaid coloring agent contained in the transparent glass ceramics, it is possible to obtain glass high in strength and a light blocking property. Further, by selecting appropriate coloring components, it is possible for glass to have, for example, an infrared transmission property.

Further, the glass ceramics may be subjected to the aforesaid chemical strengthening to have higher strength. Note that a depth of a surface compressive stress layer produced by the chemical strengthening of the glass ceramics is 6 μm to 70 μm. The reason is the same as the reason stated for the glass of the first embodiment.

Alternatively, to form the compressive stress layer on a glass surface, the crystals existing in a surface region of the glass ceramics may be changed. For example, in the glass ceramics in which a β-quartz solid solution as a main crystal is precipitated, inorganic sodium salt, organic acid sodium salt, inorganic calcium salt, or the like is appropriately used as a crystal transition aid, to cause the crystal transition of the β-quartz solid solution only in the surface region to a β-spodumene solid solution. Consequently, the compressive stress layer is formed only on the surface as is formed by the chemical strengthening, and the glass ceramics having higher strength can be obtained.

Then, as for glass compositions other than the coloring components of the glass ceramics of the colored glass housing, being the glass of the second embodiment, glass ceramics made of a publicly-known composition system can be used.

For example, in Li₂O—Al₂O₃—SiO₂-based glass ceramicses, a β-quartz solid solution and a β-spodumene solid solution (differing depending on a heat treatment condition and so on) are precipitated by crystallization processing at a predetermined temperature after nucleus formation. By making the aforesaid coloring components contained in these glasses, it is possible to obtain glass having a light transmission property and high strength, suitable for the colored glass housing of the present invention.

The crystals precipitated by the re-heating of the glass ceramics differ depending on the composition system of the glass, a trace component in the composition, a heat treatment condition, and the like. Therefore, as the main crystal, any main crystal may be used, provided that it enhances the strength of the glass. Possible examples are a β-quartz solid solution, a β-spodumene solid solution, a β-Wollastonite, and the like, but the main crystal is not limited to these.

A method of manufacturing the glass of the second embodiment is not particularly limited, but for example, appropriate amounts of various raw materials are compounded, and after the resultant is melted by being heated to about 1500° C. to 1800° C., it is made uniform by deaeration, agitation, or the like, is molded into a plate shape or the like by a known down-draw method, pressing method, roll-out method, or the like, or is molded into a block shape by casting, and after annealing, is cut to a desired shape, and is subjected to polishing or the like. Then, as a crystal precipitation step, it is kept at 400° C. to 900° C. for thirty minutes to six hours, whereby a crystal nucleus and the main crystal are precipitated. Further, when the glass ceramics is chemically strengthened, the aforesaid chemical strengthening method is used after the crystal precipitation step. Further, when the crystals in the surface region of the glass ceramics are dislocated, the crystal transition aid is applied on the surface of the glass having undergone the crystal precipitation step, followed by heat treatment. Then, the glass is annealed at room temperature or the like.

The colored glass housing of the embodiments may be molded not only into the flat plate shape but also a dented shape or a bulging shape. In this case, the glass molded into the flat plate, the block, or the like may be press-formed in a state where it is melted by re-heating. Further, the glass may be molded into a desired shape by what is called, a direct press method, that is, a method in which the molten glass is poured directly onto a press mold and the glass is press-formed. Further, portions corresponding to a display device and a connector of an electronic device may be worked at the same time as the press forming, or may be worked by cutting or the like after the press-forming.

When the glass is press-formed, a glass molding temperature at the time of the press forming is preferably low. Generally, when the glass molding temperature at the time of the press forming is high, a superalloy or ceramics poor in workability and expensive has to be used for a used die, and it deteriorates fast because of the use under the high temperature. Further, since the glass is softened at a high temperature, a great energy is needed. The colored glass housing of the embodiments contains the coloring component of 0.1% to 7% in the glass in terms of molar percentage on the oxide basis, which makes it possible to lower Tg (glass transition point) being an index of the glass molding temperature at the time of the press forming. Consequently, it is possible for the glass to be excellent in press formability, which is suitable for the press forming into an appropriate shape such as the dented shape or the bulging shape.

Further, the colored glass housing of the embodiments preferably has the radio wave transmission property. For example, in a case of a housing of a portable phone or the like which has communication elements therein and transmits or receives information by using a radio wave, imparting the radio wave transmission property to glass included in the housing suppresses deterioration of communication sensitivity ascribable to the housing.

As for the radio wave transmission property in the glass used in the colored glass housing of the embodiments, the maximum value of a dielectric tangent (tan δ) is preferably 0.02 or less at frequencies in a 50 MHz to 3.0 GHz range. It is preferably 0.015 or less, and more preferably 0.01 or less.

The colored glass housing of the embodiments is suitably used for a portable electronic device. The portable electronic device is a concept including communication devices and information devices portably usable. For example, the communication devices include a portable phone, a PHS (Personal Handy-phone System), a smartphone, a PDA (Personal Data Assistance), a PND (Portable Navigation Device, a portable car navigation system) as communication terminals, and a portable radio, a portable television set, a one-seg receiver, and so on as broadcast receivers. Further, as the information devices, there are a digital camera, a video camera, a portable music player, a sound recorder, a portable DVD player, a portable game machine, a laptop personal computer, a tablet PC, an electronic dictionary, an electronic notebook, an electronic book reader, a portable printer, a portable scanner, and so on. Further, the colored glass housing is also usable for a stationary-type electronic device and an electronic device internally mounted on an automobile. It should be noted that these examples are not limitative.

These portable electronic devices can have high strength and an aesthetic appearance when using the colored glass housing of the embodiments.

### Examples

Hereinafter, a detailed description will be given based on examples of the embodiments, but the embodiments is not limited only to these examples.

Examples of the chemically strengthened glass being the glass of the first embodiment will be described. In Examples 1 to 67 (Examples 1 to 65 are the examples, and Examples 66 to 67 are comparative examples) in Tables 1 to 8, generally used glass raw materials such as an oxide, a hydroxide, a carbonate, and a nitrate were appropriately selected so that compositions became those shown in the tables in terms of molar percentage, and they were measured so that an amount as the glass became 100 ml. Note that SO₃ described in the tables is SO₃ which is left in the glasses after sodium sulfate (Na₂SO₄) is added to the glass raw materials and is decomposed, and its calculation values are shown.

Next, this raw material mixture was put into a platinum crucible, which was put into a resistance-heating electric furnace at 1500° C. to 1600° C., and after the raw materials were melted down in about 0.5 hours, the mixture was melted for one hour, and after deforming, it was poured into a mold with about 50 mm length×about 100 mm width×about 20 mm height pre-heated to about 300° C., and was annealed at an about 1° C./minute rate, whereby a glass block was obtained. This glass block was cut into a 40 mm×40 mm size and a thickness of 0.7 mm, and a cut piece was ground, and both surfaces thereof were finally polished to mirror surfaces, whereby plate-shaped glass was obtained.

Regarding the obtained plate-shaped glass, the minimum value of an absorption constant at wavelength from 380 nm to 780 nm, a relative value expressed by an absorption constant at 550 nm wavelength/an absorption constant at 600 nm wavelength, a relative value expressed by an absorption constant at 450 nm wavelength/the absorption constant at 600 nm wavelength, a CIL (Crack Initiation Load) value, a potassium ion diffusion depth, absorbance, and a plate thickness satisfying the absorbance are also shown in Tables 1 to 8.

TABLE 1

| [mol %] | E1 | E2 | E3 | E4 | E5 | E6 | E7 | E8 | E9 |
|---|---|---|---|---|---|---|---|---|---|
| SiO₂ | 61.8 | 61.8 | 61.8 | 70.1 | 69.1 | 66.0 | 61.8 | 61.6 | 61.9 |
| B₂O₃ | 0 | 0 | 0 | 0 | 0 | 0 | 6.7 | 9.2 | 0 |
| Na₂O | 12.0 | 12.0 | 12.0 | 13.4 | 11.5 | 11.4 | 13.8 | 13.1 | 11.5 |
| K₂O | 3.9 | 3.9 | 3.9 | 0 | 0 | 2.2 | 0.5 | 0.01 | 3.8 |
| MgO | 10.1 | 5.3 | 7.7 | 5.8 | 9.6 | 5.3 | 0.02 | 0.01 | 10.5 |
| CaO | 0 | 0 | 0 | 0 | 0 | 0.3 | 0.07 | 0.02 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.7 | 12.5 | 10.1 | 6.7 | 5.8 | 10.2 | 13.4 | 12.1 | 5.8 |
| TiO₂ | 0 | 0 | 0 | 0 | 0 | 0.6 | 0 | 0 | 0 |
| ZrO₂ | 0.5 | 0.5 | 0.5 | 0 | 0 | 0 | 0 | 0 | 2.4 |
| CeO₂ | 0 | 0 | 0 | 0 | 0 | 0 | 0 | 0 | 0 |
| CoO (Co₃O₄) | 0.38 | 0.38 | 0.38 | 0.38 | 0.38 | 0.38 | 0.38 | 0.38 | 0.38 |
| Fe₂O₃ | 3.2 | 3.2 | 3.2 | 3.2 | 3.2 | 3.2 | 3.2 | 3.2 | 3.2 |
| Er₂O₃ | 0 | 0 | 0 | 0 | 0 | 0 | 0 | 0 | 0 |
| Nd₂O₃ | 0 | 0 | 0 | 0 | 0 | 0 | 0 | 0 | 0 |
| SO₃ | 0.38 | 0.38 | 0.38 | 0.37 | 0.37 | 0.38 | 0.37 | 0.37 | 0.37 |
| NiO | 0 | 0 | 0 | 0 | 0 | 0 | 0 | 0 | 0 |
| MnO₂ | 0 | 0 | 0 | 0 | 0 | 0 | 0 | 0 | 0 |
| CuO | 0 | 0 | 0 | 0 | 0 | 0 | 0 | 0 | 0 |
| Co₃O₄/Fe₂O₃ | 0.12 | 0.12 | 0.12 | 0.12 | 0.12 | 0.12 | 0.12 | 0.12 | 0.12 |
| (SiO₂ + Al₂O₃ + B₂O₃)/ | 3.57 | 3.81 | 3.69 | 4.52 | 4.97 | 4.36 | 4.56 | 4.96 | 3.59 |
| (ΣR₂O + CaO + SrO + BaO + Co₃O₄ + Fe₂O₃) | | | | | | | | | |
| (SiO₂ + Al₂O₃ + B₂O₃)/ | 3.57 | 3.81 | 3.69 | 4.52 | 4.97 | 4.36 | 4.56 | 4.96 | 3.59 |
| (ΣR₂O + CaO + SrO + BaO + Co₃O₄ + | | | | | | | | | |
| Fe₂O₃ + NiO) | | | | | | | | | |
| Absorption constant [mm⁻¹] | 1.120 | 4.870 | 1.280 | 1.260 | 1.490 | 3.050 | 4.920 | 4.920 | 1.140 |
| (minimum value at 380 to 780 wagelength) | | | | | | | | | |
| Relative value of absorption constants | 0.76 | 0.97 | 0.81 | 0.78 | 0.82 | 1.02 | 1.00 | 1.00 | 3.07 |
| (@550 nm/@600 nm) | | | | | | | | | |
| Relative value of absorption constants | 0.73 | 0.99 | 0.88 | 0.64 | 0.80 | 1.07 | 1.01 | 0.99 | 3.07 |
| (@450 nm/@600 nm) | | | | | | | | | |
| Plate thickness (mm) | 0.7 | 0.7 | 0.7 | 0.7 | 0.7 | 0.7 | 0.7 | 0.7 | 0.7 |
| Absorbance | 0.78 | 3.41 | 0.90 | 0.88 | 1.04 | 2.14 | 3.44 | 3.44 | 0.80 |
| ClL value (gf) | 320 | 193 | 290 | 406 | 700 | 524 | 277 | 1000< | 92 |
| Postassium ion diffusion depth (μm) | 35 | 43 | 45 | 27 | 19 | 32 | 44 | 31 | 30 |

E1 to E9 = Example 1 to Example 9

TABLE 2

| [mol %] | E10 | E11 | E12 | E13 | E14 | E15 | E16 | E17 | E18 |
|---|---|---|---|---|---|---|---|---|---|
| SiO₂ | 62.1 | 62.1 | 66.2 | 70.3 | 63.9 | 63.9 | 68.2 | 72.4 | 63.09 |
| B₂O₃ | 0 | 0 | 0 | 0 | 0 | 0 | 0 | 0 | 0 |
| Na₂O | 12.1 | 11.6 | 11.5 | 13.5 | 12.4 | 11.9 | 11.8 | 13.9 | 12.27 |
| K₂O | 3.8 | 3.8 | 2.2 | 0 | 4.0 | 4.0 | 2.3 | 0 | 3.93 |
| MgO | 10.1 | 10.6 | 5.3 | 5.8 | 10.4 | 10.9 | 5.5 | 6.0 | 10.3 |
| CaO | 0 | 0 | 0.3 | 0 | 0 | 0 | 0.35 | 0 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.7 | 5.8 | 10.2 | 6.7 | 8.0 | 6.0 | 10.5 | 7.0 | 7.85 |
| TiO₂ | 0 | 0 | 0.6 | 0 | 0 | 0 | 0.6 | 0 | 0 |
| ZrO₂ | 0.5 | 2.4 | 0 | 0 | 0.5 | 2.5 | 0 | 0 | 0.49 |
| CeO₂ | 0 | 0 | 0 | 0 | 0 | 0 | 0 | 0 | 0 |
| CoO (Co₃O₄) | 0 | 0 | 0 | 0 | 0.4 | 0.4 | 0.4 | 0.4 | 0.1 |
| Fe₂O₃ | 3.2 | 3.2 | 3.2 | 3.2 | 0 | 0 | 0 | 0 | 1.87 |
| Er₂O₃ | 0 | 0 | 0 | 0 | 0 | 0 | 0 | 0 | 0 |
| Nd₂O₃ | 0 | 0 | 0 | 0 | 0 | 0 | 0 | 0 | 0 |
| SO₃ | 0.38 | 0.38 | 0.38 | 0.38 | 0.39 | 0.39 | 0.39 | 0.39 | 0.1 |
| NiO | 0 | 0 | 0 | 0 | 0 | 0 | 0 | 0 | 0 |
| MnO₂ | 0 | 0 | 0 | 0 | 0 | 0 | 0 | 0 | 0 |
| CuO | 0 | 0 | 0 | 0 | 0 | 0 | 0 | 0 | 0 |
| Co₃O₄/Fe₂O₃ | — | — | — | — | — | — | — | — | 0.05 |
| (SiO₂ + Al₂O₃ + B₂O₃)/ | 3.65 | 3.65 | 4.44 | 4.61 | 4.28 | 4.29 | 5.30 | 5.55 | 3.90 |
| (ΣR₂O + CaO + SrO + BaO + Co₃O₄ + Fe₂O₃) | | | | | | | | | |
| (SiO₂ + Al₂O₃ + B₂O₃)/ | 3.65 | 3.65 | 4.44 | 4.61 | 4.28 | 4.29 | 5.30 | 5.55 | 3.90 |
| (ΣR₂O + CaO + SrO + BaO + Co₃O₄ + | | | | | | | | | |
| Fe₂O₃ + NiO) | | | | | | | | | |
| Absorption constant [mm⁻¹] | 1.060 | 1.140 | 1.830 | 1.280 | 0.080 | 0.090 | 0.060 | 0.070 | 0.486 |
| (minimum value at 380 to 780 wagelengths) | | | | | | | | | |
| Relative value of absorption constants | 1.15 | 1.16 | 1.09 | 1.12 | 0.61 | 0.58 | 0.50 | 0.67 | 0.637 |
| (@550 nm/@600 nm) | | | | | | | | | |
| Relative value of absorption constants | 2.21 | 2.19 | 1.23 | 1.74 | 0.17 | 0.18 | 0.16 | 0.15 | 0.641 |
| (@450 nm/@600 nm) | | | | | | | | | |
| Plate thickness (mm) | 0.7 | 0.7 | 0.7 | 0.7 | 9.1 | 8.6 | 12.3 | 10.6 | 1.7 |
| Absorbance | 0.74 | 0.80 | 1.28 | 0.90 | 0.73 | 0.77 | 0.74 | 0.74 | 0.82 |
| ClL value (gf) | 252 | 100 | 569 | 311 | 722 | 120 | 826 | 763 | — |
| Postassium ion diffusion depth (μm) | 35 | 31 | 33* | 28* | 47* | 40 | 43* | 38* | — |

E10 to E18 = Example 10 to Example 18

TABLE 3

| [mol %] | E19 | E20 | E21 | E22 | E23 | E24 | E25 | E26 | E27 |
|---|---|---|---|---|---|---|---|---|---|
| SiO₂ | 63.8 | 64.0 | 63.42 | 63.48 | 63.54 | 62.59 | 63.21 | 63.69 | 63.8 |
| B₂O₃ | 0 | 0 | 0 | 0 | 0 | 0 | 0 | 0 | 0 |
| Na₂O | 12.41 | 12.44 | 12.33 | 12.34 | 12.35 | 12.17 | 12.29 | 12.38 | 12.4 |
| K₂O | 3.97 | 3.98 | 3.94 | 3.95 | 3.95 | 3.89 | 3.93 | 3.96 | 3.97 |
| MgO | 10.42 | 10.45 | 10.36 | 10.37 | 10.38 | 10.22 | 10.32 | 10.4 | 10.42 |
| CaO | 0 | 0 | 0 | 0 | 0 | 0 | 0 | 0 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.94 | 7.96 | 7.89 | 7.9 | 7.91 | 7.79 | 7.86 | 7.92 | 7.94 |
| TiO₂ | 0 | 0 | 0 | 0 | 0 | 0.24 | 0.25 | 0.5 | 0.25 |
| ZrO₂ | 0.5 | 0.5 | 0.49 | 0.49 | 0.49 | 0.41 | 0.42 | 0.5 | 0.42 |
| CeO₂ | 0 | 0 | 0 | 0 | 0 | 0 | 0 | 0 | 0 |
| CoO (Co₃O₄) | 0.07 | 0.07 | 0.04 | 0.04 | 0.04 | 0 | 0 | 0.06 | 0.05 |
| Fe₂O₃ | 0.015 | 0.02 | 1.13 | 1.14 | 1.14 | 0 | 0 | 0.01 | 0.018 |
| Er₂O₃ | 0 | 0 | 0 | 0 | 0 | 0 | 0 | 0 | 0 |
| Nd₂O₃ | 0 | 0 | 0 | 0 | 0 | 0 | 0 | 0 | 0 |
| SO₃ | 0.1 | 0.1 | 0.1 | 0.1 | 0.1 | 0.1 | 0.1 | 0.1 | 0.1 |
| NiO | 0.75 | 0.5 | 0.3 | 0.2 | 0.1 | 0.64 | 0.65 | 0.5 | 0.65 |
| MnO₂ | 0 | 0 | 0 | 0 | 0 | 0 | 0 | 0 | 0 |
| CuO | 0 | 0 | 0 | 0 | 0 | 1.95 | 0.98 | 0 | 0 |
| Co₃O₄/Fe₂O₃ | 4.67 | 3.50 | 0.04 | 0.04 | 0.04 | — | — | 6.00 | 2.78 |
| (SiO₂ + Al₂O₃ + B₂O₃)/ | 4.36 | 4.36 | 4.09 | 4.09 | 4.09 | 4.36 | 4.38 | 4.36 | 4.36 |
| (ΣR₂O + CaO + SrO + BaO + Co₃O₄ + Fe₂O₃) | | | | | | | | | |
| (SiO₂ + Al₂O₃ + B₂O₃)/ | 4.17 | 4.23 | 4.02 | 4.04 | 4.06 | 4.21 | 4.21 | 4.23 | 4.20 |
| (ΣR₂O + CaO + SrO + BaO + Co₃O₄ + | | | | | | | | | |
| Fe₂O₃ + NiO) | | | | | | | | | |
| Absorption constant [mm⁻¹] | 0.096 | 0.076 | 0.361 | 0.357 | 0.337 | 0.741 | 0.333 | 0.083 | 0.090 |
| (minimum value at 380 to 780 wagelengths) | | | | | | | | | |
| Relative value of absorption constants | 0.771 | 0.701 | 0.757 | 0.720 | 0.667 | 0.996 | 1.116 | 0.799 | 0.817 |
| (@550 nm/@600 nm) | | | | | | | | | |
| Relative value of absorption constants | 0.857 | 0.654 | 0.944 | 0.824 | 0.668 | 1.663 | 1.887 | 0.752 | 0.933 |
| (@450 nm/@600 nm) | | | | | | | | | |
| Plate thickness (mm) | 7.3 | 9.2 | 2.9 | 3.1 | 2.1 | 1.6 | 2.9 | 8.4 | 7.8 |
| Absorbance | 0.70 | 0.70 | 1.04 | 1.11 | 0.80 | 1.16 | 0.97 | 0.70 | 0.70 |
| ClL value (gf) | — | — | — | — | — | — | — | — | — |
| Postassium ion diffusion depth (μm) | — | — | — | — | — | — | — | — | — |

E19 to E27 = Example 19 to Example 27

TABLE 4

| [mol %] | E28 | E29 | E30 | E31 | E32 | E33 | E34 | E35 | E36 |
|---|---|---|---|---|---|---|---|---|---|
| SiO₂ | 63.22 | 63.0 | 63.19 | 64.8 | 63.31 | 63.69 | 63.48 | 64.08 | 64.4 |
| B₂O₃ | 0 | 0 | 0 | 0 | 0 | 0 | 0 | 0 | 0 |
| Na₂O | 12.29 | 12.25 | 12.28 | 13.79 | 12.31 | 12.78 | 12.34 | 13.63 | 13.7 |
| K₂O | 3.93 | 3.92 | 3.93 | 3.94 | 3.94 | 3.93 | 3.95 | 3.9 | 3.91 |
| MgO | 10.32 | 10.29 | 10.32 | 7.39 | 10.34 | 9.34 | 10.37 | 7.3 | 7.34 |
| CaO | 0 | 0 | 0 | 0 | 0 | 0 | 0 | 0 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.87 | 7.84 | 7.86 | 7.88 | 7.88 | 7.86 | 7.9 | 7.79 | 7.83 |
| TiO₂ | 0.25 | 0.73 | 0.49 | 0.25 | 0.25 | 0.25 | 0.25 | 0.24 | 0.24 |
| ZrO₂ | 0.49 | 0.49 | 0.49 | 0.42 | 0.49 | 0.42 | 0.42 | 0.41 | 0.42 |
| CeO₂ | 0 | 0 | 0 | 0 | 0 | 0 | 0 | 0 | 0 |
| CoO (Co₃O₄) | 0.05 | 0.06 | 0.06 | 0.06 | 0.06 | 0.04 | 0.05 | 0.05 | 0.05 |
| Fe₂O₃ | 1.03 | 1.03 | 1.03 | 1.03 | 1.03 | 0.025 | 0.015 | 0.02 | 0.01 |
| Er₂O₃ | 0 | 0 | 0 | 0 | 0 | 0 | 0 | 0 | 0 |
| Nd₂O₃ | 0 | 0 | 0 | 0 | 0 | 0 | 0 | 0 | 0 |
| SO₃ | 0.1 | 0.1 | 0.1 | 0.1 | 0.1 | 0.1 | 0.1 | 0.1 | 0.1 |
| NiO | 0.44 | 0.29 | 0.25 | 0.34 | 0.3 | 0.61 | 0.65 | 0.54 | 0.54 |
| MnO₂ | 0 | 0 | 0 | 0 | 0 | 0 | 0 | 0 | 0 |
| CuO | 0 | 0 | 0 | 0 | 0 | 0.98 | 0.49 | 1.95 | 1.47 |
| Co₃O₄/Fe₂O₃ | 0.05 | 0.0 | 0.06 | 0.06 | 0.06 | 1.60 | 3.33 | 2.50 | 5.00 |
| (SiO₂ + Al₂O₃ + B₂O₃)/ | 4.11 | 4.10 | 4.11 | 3.86 | 4.11 | 4.27 | 4.36 | 4.08 | 4.09 |
| (ΣR₂O + CaO + SrO + BaO + Co₃O₄ + Fe₂O₃) | | | | | | | | | |
| (SiO₂ + Al₂O₃ + B₂O₃)/ | 4.01 | 4.04 | 4.05 | 3.79 | 4.04 | 4.12 | 4.20 | 3.96 | 3.97 |
| (ΣR₂O + CaO + SrO + BaO + Co₃O₄ + | | | | | | | | | |
| Fe₂O₃ + NiO) | | | | | | | | | |
| Absorption constant [mm⁻¹] | 0.350 | 0.342 | 0.331 | 0.340 | 0.322 | 0.308 | 0.184 | 0.492 | 0.373 |
| (minimum value at 380 to 780 wagelengths) | | | | | | | | | |
| Relative value of absorption constants | 0.794 | 0.725 | 0.702 | 0.738 | 0.703 | 0.791 | 0.807 | 0.757 | 0.769 |
| (@550 nm/@600 nm) | | | | | | | | | |
| Relative value of absorption constants | 0.966 | 0.842 | 0.753 | 0.634 | 0.773 | 0.874 | 0.956 | 0.666 | 0.670 |
| (@450 nm/@600 nm) | | | | | | | | | |
| Plate thickness (mm) | 2.4 | 2.2 | 2.2 | 2.4 | 3.1 | 2.4 | 4.0 | 2.1 | 2.3 |
| Absorbance | 0.84 | 0.76 | 0.73 | 0.80 | 0.99 | 0.74 | 0.73 | 1.03 | 0.87 |
| ClL value (gf) | — | — | — | — | — | — | — | — | — |
| Postassium ion diffusion depth (μm) | — | — | — | — | — | — | — | — | — |

E28 to E36 = Example 28 to Example 36

TABLE 5

| [mol %] | E37 | E38 | E39 | E40 | E41 | E42 | E43 | E44 | E45 |
|---|---|---|---|---|---|---|---|---|---|
| SiO₂ | 64.97 | 64.84 | 63.17 | 64.65 | 64.08 | 63.43 | 63.68 | 63.13 | 63.44 |
| B₂O₃ | 0 | 0 | 0 | 0 | 0 | 0 | 0 | 0 | 0 |
| Na₂O | 13.82 | 13.8 | 12.28 | 13.75 | 13.63 | 12.53 | 12.78 | 12.27 | 12.33 |
| K₂O | 3.95 | 3.94 | 3.97 | 3.93 | 3.90 | 3.93 | 3.93 | 3.93 | 3.95 |
| MgO | 7.4 | 7.39 | 10.32 | 7.37 | 7.30 | 9.83 | 9.34 | 10.31 | 10.36 |
| CaO | 0 | 0 | 0 | 0 | 0 | 0 | 0 | 0 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.9 | 7.88 | 7.86 | 7.86 | 7.79 | 7.86 | 7.86 | 7.85 | 7.89 |
| TiO₂ | 0.25 | 0.25 | 0.25 | 0.25 | 0.24 | 0.25 | 0.25 | 0.25 | 0.25 |
| ZrO₂ | 0.42 | 0.42 | 0.42 | 0.42 | 0.41 | 0.42 | 0.42 | 0.49 | 0.49 |
| CeO₂ | 0 | 0 | 0 | 0 | 0 | 0 | 0 | 0.98 | 0.49 |
| CoO (Co₃O₄) | 0.05 | 0.05 | 0.05 | 0.05 | 0.05 | 0.05 | 0.04 | 0.05 | 0.05 |
| Fe₂O₃ | 0.025 | 0.021 | 0.016 | 0.015 | 0.022 | 0.01 | 0 | 0.012 | 0.012 |
| Er₂O₃ | 0 | 0 | 0 | 0 | 0 | 0 | 0 | 0 | 0 |
| Nd₂O₃ | 0 | 0 | 0 | 0 | 0 | 0 | 0 | 0 | 0 |
| SO₃ | 0.1 | 0.1 | 0.1 | 0.1 | 0.1 | 0.1 | 0.1 | 0.1 | 0.1 |
| NiO | 0.55 | 0.55 | 0.64 | 0.64 | 0.54 | 0.63 | 0.62 | 0.64 | 0.65 |
| MnO₂ | 0 | 0 | 0 | 0 | 0 | 0 | 0 | 0 | 0 |
| CuO | 0.59 | 0.79 | 0.98 | 0.98 | 1.95 | 0.98 | 0.98 | 0 | 0 |
| Co₃O₄/Fe₂O₃ | 2.00 | 2.38 | 3.13 | 3.33 | 2.27 | 5.00 | — | 4.17 | 4.17 |
| (SiO₂ + Al₂O₃ + B₂O₃)/ | 4.08 | 4.08 | 4.35 | 4.09 | 4.08 | 4.32 | 4.27 | 4.36 | 4.36 |
| (ΣR₂O + CaO + SrO + BaO + Co₃O₄ + Fe₂O₃) | | | | | | | | | |
| (SiO₂ + Al₂O₃ + B₂O₃)/ | 3.96 | 3.96 | 4.19 | 3.94 | 3.96 | 4.16 | 4.12 | 4.20 | 4.20 |
| (ΣR₂O + CaO + SrO + BaO + Co₃O₄ + | | | | | | | | | |
| Fe₂O₃ + NiO) | | | | | | | | | |
| Absorption constant [mm⁻¹] | 0.149 | 0.188 | 0.349 | 0.247 | 0.543 | 0.325 | 0.307 | 0.125 | 0.121 |
| (minimum value at 380 to 780 wagelengths) | | | | | | | | | |
| Relative value of absorption constants | 0.784 | 0.779 | 0.771 | 0.797 | 0.745 | 0.779 | 0.801 | 0.821 | 0.816 |
| (@550 nm/@600 nm) | | | | | | | | | |
| Relative value of absorption constants | 0.632 | 0.626 | 0.901 | 0.696 | 0.649 | 0.888 | 0.902 | 1.046 | 1.014 |
| (@450 nm/@600 nm) | | | | | | | | | |
| Plate thickness (mm) | 5.0 | 3.8 | 3.4 | 3.6 | 2.1 | 2.3 | 3.3 | 5.7 | 6.2 |
| Absorbance | 0.75 | 0.72 | 1.20 | 0.89 | 1.14 | 0.75 | 1.02 | 0.71 | 0.75 |
| ClL value (gf) | — | — | — | — | — | — | — | — | — |
| Postassium ion diffusion depth (μm) | — | — | — | — | — | — | — | — | — |

E37 to E45 = Example 37 to Example 45

TABLE 6

| [mol %] | E46 | E47 | E48 | E49 | E50 | E51 | E52 | E53 | E54 |
|---|---|---|---|---|---|---|---|---|---|
| SiO₂ | 63.59 | 63.69 | 63.03 | 62.97 | 63.12 | 63.2 | 63.12 | 63.22 | 63.25 |
| B₂O₃ | 0 | 0 | 0 | 0 | 0 | 0 | 0 | 0 | 0 |
| Na₂O | 12.36 | 12.38 | 12.25 | 12.24 | 12.27 | 12.29 | 12.27 | 12.29 | 12.3 |
| K₂O | 3.96 | 3.96 | 3.92 | 3.92 | 3.93 | 3.93 | 3.93 | 3.93 | 3.93 |
| MgO | 10.38 | 10.4 | 10.29 | 10.28 | 10.31 | 10.32 | 10.31 | 10.32 | 10.33 |
| CaO | 0 | 0 | 0 | 0 | 0 | 0 | 0 | 0 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.91 | 7.92 | 7.84 | 7.83 | 7.85 | 7.86 | 7.85 | 7.87 | 7.87 |
| TiO₂ | 0.25 | 0.25 | 0.25 | 0.24 | 0.25 | 0.25 | 0.25 | 0.25 | 0.25 |
| ZrO₂ | 0.49 | 0.5 | 0.49 | 0.49 | 0.49 | 0.49 | 0.49 | 0.49 | 0.49 |
| CeO₂ | 0.25 | 0.1 | 0 | 0 | 0 | 0 | 0 | 0 | 0 |
| CoO (Co₃O₄) | 0.05 | 0.05 | 0.06 | 0.06 | 0.06 | 0.06 | 0.06 | 0.06 | 0.06 |
| Fe₂O₃ | 0.02 | 0.014 | 1.03 | 1.03 | 1.03 | 1.03 | 1.03 | 1.03 | 1.03 |
| Er₂O₃ | 0 | 0 | 0.39 | 0 | 0 | 0 | 0 | 0 | 0 |
| Nd₂O₃ | 0 | 0 | 0 | 0.49 | 0.25 | 0.12 | 0 | 0 | 0 |
| SO₃ | 0.1 | 0.1 | 0.1 | 0.1 | 0.1 | 0.1 | 0.1 | 0.1 | 0.1 |
| NiO | 0.65 | 0.65 | 0.34 | 0.34 | 0.34 | 0.34 | 0.34 | 0.34 | 0.34 |
| MnO₂ | 0 | 0 | 0 | 0 | 0 | 0 | 0.25 | 0.1 | 0.05 |
| CuO | 0 | 0 | 0 | 0 | 0 | 0 | 0 | 0 | 0 |
| Co₃O₄/Fe₂O₃ | 2.50 | 3.57 | 0.06 | 0.06 | 0.06 | 0.06 | 0.06 | 0.06 | 0.06 |
| (SiO₂ + Al₂O₃ + B₂O₃)/ | 4.36 | 4.37 | 4.11 | 4.11 | 4.10 | 4.11 | 4.10 | 4.11 | 4.11 |
| (ΣR₂O + CaO + SrO + | | | | | | | | | |
| BaO + Co₃O₄ + Fe₂O₃) | | | | | | | | | |
| (SiO₂ + Al₂O₃ + B₂O₃)/ | 4.20 | 4.20 | 4.03 | 4.03 | 4.03 | 4.03 | 4.03 | 4.03 | 4.03 |
| (ΣR₂O + CaO + SrO + | | | | | | | | | |
| BaO + Co₃O₄ + Fe₂O₃ + NiO) | | | | | | | | | |
| Absorption constant [mm⁻¹] | 0.115 | 0.120 | 0.347 | 0.348 | 0.346 | 0.356 | 0.340 | 0.339 | 0.342 |
| (minimum value at 380 to 780 wagelengths) | | | | | | | | | |
| Relative value of absorption constants | 0.825 | 0.819 | 0.735 | 0.690 | 0.707 | 0.716 | 0.746 | 0.744 | 0.722 |
| (@550 nm/@600 nm) | | | | | | | | | |
| Relative value of absorption constants | 1.005 | 0.985 | 0.850 | 0.810 | 0.825 | 0.822 | 0.849 | 0.831 | 0.827 |
| (@450 nm/@600 nm) | | | | | | | | | |
| Plate thickness (mm) | 6.3 | 6.7 | 2.4 | 2.4 | 2.3 | 2.2 | 2.1 | 2.7 | 2.7 |
| Absorbance | 0.73 | 0.80 | 0.83 | 0.84 | 0.78 | 0.80 | 0.73 | 0.90 | 0.94 |
| ClL value (gf) | — | — | — | — | — | — | — | — | — |
| Postassium ion diffusion depth (μm) | — | — | — | — | — | — | — | — | — |

E46 to E54 = Example 46 to Example 54

TABLE 7

| [mol %] | E55 | E56 | E57 | E58 | E59 | E60 | E61 | E62 | E63 |
|---|---|---|---|---|---|---|---|---|---|
| SiO₂ | 63.27 | 62.99 | 63.12 | 63.72 | 63.69 | 62.63 | 63.17 | 64.65 | 64.08 |
| B₂O₃ | 0 | 0 | 0 | 0 | 0 | 0 | 0 | 0 | 0 |
| Na₂O | 12.3 | 12.25 | 12.27 | 12.39 | 12.38 | 12.18 | 12.28 | 13.75 | 13.63 |
| K₂O | 3.94 | 3.92 | 3.93 | 3.96 | 3.97 | 3.9 | 3.93 | 3.93 | 3.90 |
| MgO | 10.33 | 10.29 | 10.31 | 10.4 | 10.42 | 10.23 | 10.32 | 7.37 | 7.30 |
| CaO | 0 | 0 | 0 | 0 | 0 | 0 | 0 | 0 | 0 |
| BaO | 0 | 0 | 0 | 0 | 0 | 0 | 0 | 0 | 0 |
| SrO | 0 | 0 | 0 | 0 | 0 | 0 | 0 | 0 | 0 |
| Al₂O₃ | 7.87 | 7.84 | 7.85 | 7.93 | 7.94 | 7.79 | 7.86 | 7.86 | 7.79 |
| TiO₂ | 0.25 | 0 | 0 | 0.25 | 0.25 | 0.24 | 0.25 | 0.25 | 0.24 |
| ZrO₂ | 0.49 | 0.49 | 0.49 | 0.5 | 0.5 | 0.41 | 0.42 | 0.42 | 0.41 |
| CeO₂ | 0 | 0 | 0 | 0 | 0 | 0 | 0 | 0 | 0 |
| CoO (Co₃O₄) | 0.06 | 0.07 | 0.07 | 0.04 | 0.06 | 0.03 | 0.05 | 0.05 | 0.05 |
| Fe₂O₃ | 1.03 | 1.67 | 1.67 | 0.25 | 0.018 | 0.03 | 0.016 | 0.015 | 0.022 |
| Er₂O₃ | 0 | 0.39 | 0.2 | 0 | 0 | 0 | 0 | 0 | 0 |
| Nd₂O₃ | 0 | 0 | 0 | 0 | 0 | 0 | 0 | 0 | 0 |
| SO₃ | 0.1 | 0.1 | 0.1 | 0.1 | 0.1 | 0.1 | 0.1 | 0.1 | 0.1 |
| NiO | 0.34 | 0 | 0 | 0.46 | 0.74 | 0.54 | 0.64 | 0.64 | 0.54 |
| MnO₂ | 0.01 | 0 | 0 | 0 | 0 | 0 | 0 | 0 | 0 |
| CuO | 0 | 0 | 0 | 0 | 0 | 1.95 | 0.98 | 0.98 | 1.95 |
| Co₃O₄/Fe₂O₃ | 0.06 | 0.04 | 0.04 | 0.16 | 3.33 | 1.00 | 3.13 | 3.33 | 2.27 |
| (SiO₂ + Al₂O₃ + B₂O₃)/ | 4.11 | 3.95 | 3.96 | 4.31 | 4.36 | 4.36 | 4.36 | 4.09 | 4.08 |
| (ΣR₂O + CaO + SrO + BaO + Co₃O₄ + Fe₂O₃) | | | | | | | | | |
| (SiO₂ + Al₂O₃ + B₂O₃)/ | 4.03 | 3.95 | 3.96 | 4.19 | 4.17 | 4.22 | 4.20 | 3.94 | 3.96 |
| (ΣR₂O + CaO + SrO + BaO + Co₃O₄ + | | | | | | | | | |
| Fe₂O₃ + NiO) | | | | | | | | | |
| Absorption constant [mm⁻¹] | 0.349 | 0.419 | 0.420 | 0.164 | 0.088 | 0.717 | 0.349 | 0.247 | 0.543 |
| (minimum value at 380 to 780 wagelengths) | | | | | | | | | |
| Relative value of absorption constants | 0.734 | 0.638 | 0.635 | 0.791 | 0.813 | 0.774 | 0.771 | 0.797 | 0.745 |
| (@550 nm/@600 nm) | | | | | | | | | |
| Relative value of absorption constants | 0.830 | 0.632 | 0.620 | 0.920 | 0.956 | 0.992 | 0.901 | 0.696 | 0.649 |
| (@450 nm/@600 nm) | | | | | | | | | |
| Plate thickness (mm) | 2.3 | 2.0 | 2.4 | — | 8.4 | 1.7 | 3.1 | 3.6 | 2.1 |
| Absorbance | 0.82 | 0.84 | 0.99 | — | 0.74 | 1.23 | 1.08 | 0.89 | 1.14 |
| ClL value (gf) | — | — | — | 4.5 | 1.7 | 3.1 | — | — | — |
| Postassium ion diffusion depth (μm) | — | — | — | 0.74 | 1.23 | 1.08 | — | — | — |

E55 to E63 = Example 55 to Example 63

TABLE 8

| [mol %] | E64 | E65 | E66 | E67 |
|---|---|---|---|---|
| SiO₂ | 63.43 | 63.68 | 72.0 | 64.3 |
| B₂O₃ | 0 | 0 | 0 | 0 |
| Na₂O | 12.53 | 12.78 | 12.6 | 12.0 |
| K₂O | 3.93 | 3.93 | 0.2 | 4.0 |
| MgO | 9.83 | 9.34 | 5.5 | 11.0 |
| CaO | 0 | 0 | 8.6 | 0.1 |
| BaO | 0 | 0 | 0 | 0 |
| SrO | 0 | 0 | 0 | 0.1 |
| Al₂O₃ | 7.86 | 7.86 | 1.1 | 6.0 |
| TiO₂ | 0.25 | 0.25 | 0 | 0 |
| ZrO₂ | 0.42 | 0.42 | 0 | 2.5 |
| CeO₂ | 0 | 0 | 0 | 0 |
| CoO (Co₃O₄) | 0.05 | 0.04 | 0 | 0 |
| Fe₂O₃ | 0.013 | 0.01 | 0 | 0.01 |
| Er₂O₃ | 0 | 0 | 0 | 0 |
| Nd₂O₃ | 0 | 0 | 0 | 0 |
| SO₃ | 0.1 | 0.1 | 0 | 0.09 |
| NiO | 0.63 | 0.62 | 0 | 0 |
| MnO₂ | 0 | 0 | 0 | 0 |
| CuO | 0.98 | 0.98 | 0 | 0 |
| Co₃O₄/Fe₂O₃ | 3.85 | 4.00 | — | 0 |
| (SiO₂ + Al₂O₃ + B₂O₃)/ | 4.31 | 4.27 | 3.42 | 4.34 |
| (ΣR₂O + CaO + SrO + BaO + Co₃O₄ + Fe₂O₃) | | | | |
| (SiO₂ + Al₂O₃ + B₂O₃)/ | 4.16 | 4.12 | 3.42 | 4.34 |
| (ΣR₂O + CaO + SrO + BaO + Co₃O₄ + Fe₂O₃ + NiO) | | | | |
| Absorption constant [mm⁻¹] | 0.325 | 0.307 | — | 0 |
| (minimum value at 380 to 780 wavelengths) | | | | |
| Relative value of absorption constants | 0.779 | 0.801 | — | 0 |
| (@550 nm/@600 nm) | | | | |
| Relative value of absorption constants | 0.888 | 0.902 | — | 0 |
| (@450 nm/@600 nm) | | | | |
| Plate thickness (mm) | 2.3 | 3.3 | — | — |
| Absorbance | 0.75 | 1.02 | — | — |
| CIL value (gf) | — | — | — | 300 |
| Postassium ion diffusion depth (μm) | — | — | — | 45 |

E64 to E67 = Example 64 to Example 67

The absorption constant was found by the following method. A thickness t of the plate-shaped glass whose both surfaces are mirror-polished is measured by a caliper. Spectral transmittance T of this glass is measured by using an ultraviolet-visible/near-infrared spectrophotometer (V-570 manufactured by JASCO Corporation). The absorption constant β is calculated by using a relational expression T=10^{-βt}. Then, the minimum value of the absorption constant at wavelength from 380 nm to 780 nm is found.

Further, the relative value expressed by the absorption constant at 550 nm wavelength/the absorption constant at 600 nm wavelength and the relative value expressed by the absorption constant at 450 nm wavelength/the absorption constant at 600 nm wavelength are relative values calculated by substituting the above calculated absorption constants at the target wavelengths in the aforesaid expressions.

The CIL value was found by the following method. A plate-shaped glass whose both surfaces are mirror-polished is prepared. By a Vickers hardness testing machine, a Vickers indenter is pushed in for 15 seconds, thereafter, the Vickers indenter is removed, and the vicinity of an indentation is observed 15 seconds later. In the observation, how many cracks are generated from a corner of the indentation is examined. The measurement is conducted for ten glasses under each of indentation loads 50 gf, 100 gf, 200 gf, 300 gf, 500 gf, and 1 kgf of the Vickers indenter. An average value of the number of the generated cracks is calculated for each load. A relation of the load and the number of the cracks is found by regression calculation by using a sigmoid function. From the result of the regression calculation, the load at which the number of the cracks becomes two is defined as the CIL value (gf) of the glass.

The potassium ion depth was measured based on a potassium concentration analysis in a depth direction by using EPMA (Electron Probe Micro Analyzer).

Further, a found value of the absorbance differs depending on an intended use, and here the absorbance was appropriately set so as to become 0.7 or more. Then, the plate thickness satisfying this absorbance was found by calculating the thickness of the glass plate with which the set absorbance is obtained, from the minimum value of the absorption constant calculated above.

From the above result, it is understood that the glasses of the above Examples can achieve the desired absorbance at wavelength from 380 nm to 780 nm when the thickness thereof is 5 mm or less, and absorb a predetermined amount or more of light with wavelengths in the visible range. The use of these glasses in the housing of the electronic device makes it possible to obtain a high light blocking property.

Further, from the above result of the absorption constants, in the glasses of the examples 11 to 14 being the Examples containing only Fe₂O₃ as the coloring component, the relative values of the absorption constants (the absorption constant at 450 nm wavelength/the absorption constant at 600 nm wavelength and the absorption constant at 550 nm wavelength/the absorption constant at 600 nm wavelength) are large, and therefore, there is no problem in view of the light blocking property but since the glasses look brownish or greenish, which is a cause of a decrease in yields in the application requiring the color tone of coal black. On the other hand, in the glasses of the examples 1 to 8 being the Examples in which Co₃O₄ is added together with Fe₂O₃ and the glasses of the Examples containing the other combination of the coloring components, the relative values of the absorption constants (the absorption constant at 450 nm wavelength/the absorption constant at 600 nm wavelength and the absorption constant at 550 nm wavelength/the absorption constant at 600 nm wavelength) are within a 0.7 to 1.2 range, and therefore, it is seen that they are each glass absorbing light in the visible range on an average level. Therefore, it is possible to obtain, for example, black glass having a color tone of coal black different from brownish black and bluish black.

From the above result of the CIL value, it is seen that the glasses of the Examples are each glass not easily suffering a scratch and having high strength. Glass not yet chemically strengthened suffers a scratch during its manufacturing step and transportation, and the scratch becomes a starting point of breakage after the chemical strengthening to become a cause to lower the strength of the glass. The CIL value of ordinary soda lime glass is, for example, about 150 gf, while the CIL values of the glasses of the examples 1 to 8, the example 13, and the example 14 being the Examples are larger than that of the soda lime glass, and therefore, it can be inferred that the glass having high strength even after the chemical strengthening can be obtained.

In order to confirm the effect of Fe₂O₃ and Co₃O₄ regarding the number of bubbles, the number of bubbles was confirmed in those containing both Fe₂O₃ and Co₃O₄, those containing only Fe₂O₃, and those containing only Co₃O₄, while the glass components other than Fe₂O₃ and Co₃O₄ and their contents were set the same.

The number of bubbles was measured at four places in a 0.6 cm³ region of each of the aforesaid plate-shaped glasses under a high luminance light source (LA-100T manufactured by Hayashi Watch-Works Co., Ltd.), and an average value of these measurement values was converted to a value per unit area (cm₃), and this value is shown as the number of bubbles.

The number of bubbles is greatly influenced by the composition of base glass and a melting temperature, and therefore, the comparison was made in those in which the components other than Fe₂O₃ and Co₃O₄ and their contents were the same as described above, under the same melting temperature. The result is shown in Table 9.

TABLE 9

| | Containing | Containing | Containing |
|---|---|---|---|
| | Fe₂O, Co₃O₄ | only Fe₂O₃ | only Co₃O₄ |
| Number of bubbles [pieces/cm³] | Example 1 | Example 10 | Example 14 |
| Melting temperature: 1500° C. | 42 | 65 | 59 |
| Number of bubbles [pieces/cm³] | Example 9 | Example 11 | Example 15 |
| Melting temperature: 1500° C. | 5 | 22 | 8 |
| Number of bubbles [pieces/cm³] | Example 6 | Example 12 | Example 16 |
| Melting temperature: 1500° C. | 26 | 40 | 78 |
| Number of bubbles [pieces/cm³] | Example 4 | Example 13 | Example 17 |
| Melting temperature: 1500° C. | 27 | 32 | 70 |

From this result, in any of the glass compositions, those containing both Fe₂O₃ and Co₃O₄ have a smaller number of bubbles than those containing only Fe₂O₃ and those containing only Co₃O₄. This supports that the coexistence of Co₃O₄ and Fe₂O₃ helps exhibiting the bubble eliminating effect when the glass melts. That is, a possible reason for this is that O₂ bubbles released when trivalent iron becomes bivalent iron in a high temperature state is absorbed when cobalt is oxidized, and as a result the O₂ bubbles are reduced and the bubble eliminating effect is obtained.

In order to evaluate press-formability of the glass, glasses containing coloring components (here, Fe₂O₃ and Co₃O₄) and glasses not containing the coloring components were prepared, and Tg (glass transition point temperature) of these glasses was measured. Tg of the glass was 597° C. in the example 9 (Example), while it was 620° C. in the example 67 (comparative example, glass with Fe₂O₃ and Co₃O₄ being removed from the example 9). Further, it was 596° C. in the example 1 (Example), while it was 604° C. in the example 68 (comparative example, glass with Fe₂O₃ and Co₃O₄ being removed from the example 1). Further, it was 606° C. in the example 4 (Example), while it was 617° C. in the example 69 (comparative example, glass with Fe₂O₃ and Co₃O₄ being removed from the example 4). From the above, in the glasses of the Examples, since a predetermined amount of the coloring components are contained therein, it is possible to lower Tg of the glass and decrease a glass molding temperature at the time of the press forming. Therefore, it is possible for this glass to have excellent press formability, which is preferable for glass used in the application where it is press-formed into an appropriate shape such as a dented shape or a bulging shape, such as, for example, a using glass for housing.

The chemical strengthening of the chemically strengthened glass of the embodiments is performed as follows, for example. Specifically, these glasses are immersed in a KNO₃ molten salt (100%) at about 425° C. for six hours to be chemically strengthened. The potassium concentration analysis in the depth direction of each of the glasses shows that ion exchange occurs at a depth of 5 μm to 100 μm from the surface, and a compressive stress layer is generated.

The glasses of the examples 1 to 67 were chemically strengthened as follows. Specifically, glasses were prepared in such a manner that these glasses were each worked into a shape of 4 mm×4 mm×0.7 mmt, their 4 mm×4 mm surfaces were mirror-finished and other surfaces thereof were worked to #1000 finish. These glasses were immersed in a 425° C. KNO₃ molten salt (100%) for six hours to be chemically strengthened. Results obtained when the potassium concentration analysis was conducted in the depth direction by using EPMA regarding the glasses having undergone the chemical strengthening are shown as the potassium ion diffusion depth (unit: μm) in Tables 1 to 8. Note that estimated values are shown for the examples 12 to 14 and the examples 16, 17.

As shown in the tables, under the aforesaid chemical strengthening condition, a sufficient potassium ion diffusion depth is obtained, from which it is inferred that a surface compressive stress layer depth of the surface compressive stress layer is also a corresponding depth. It is thought that as a result, a necessary and sufficient strength improving effect is obtained in the glasses of the Examples owing to the chemical strengthening.

The glasses of the example 1, the example 27, the example 33, the examples 39 to 43, and the example 66 were chemically strengthened as follows. Specifically, glasses were prepared in such a manner that these glasses were each worked into a shape of 4 mm×4 mm×0.7 mm, 4×4 mm surfaces thereof were mirror-finished, and other surfaces thereof were worked to #1000 finish. These glasses were each immersed in a 425° C. molten salt made of KNO₃ (99%) and NaNO₃ (1%) for six hours to be chemically strengthened. Regarding each of the glasses having undergone the chemical strengthening, a surface compressive stress (CS) and a depth of a surface compressive stress layer (DOL) were measured by using a surface stress measuring device. Evaluation results are shown in Table 10. Note that the surface stress measuring device is a device that uses the fact that due to a difference in refractive index of the compressive stress layer formed on a glass surface from other glass portions where the compressive stress layer does not exist, an optical waveguide effect is exhibited. Further, as a light source of the surface stress measuring device, a LED whose center wavelength was 795 nm was used.

TABLE 10

| | E1 | E27 | E33 | E39 | E40 | E41 | E42 | E43 | E66 |
|---|---|---|---|---|---|---|---|---|---|
| Surface | 885 | 794 | 784 | 853 | 817 | 797 | 767 | 774 | 607 |
| compressive | | | | | | | | | |
| Stress | | | | | | | | | |
| CS [Mpa] | | | | | | | | | |
| Depth of | 28 | 42 | 36 | 33 | 41 | 34 | 36 | 39 | 15 |
| surface | | | | | | | | | |
| compressive | | | | | | | | | |
| stress layer | | | | | | | | | |
| DOL [μm] | | | | | | | | | |

E = Example

As shown in Table 10, in the glasses of the example 1, the example 27, the example 33, and the examples 39 to 43, a sufficient surface compressive stress and a sufficient depth of the surface compressive stress layer are obtained under the aforesaid chemical strengthening condition. It is thought that as a result, a necessary and sufficient effect of improving the strength is obtained by the chemical strengthening in the glasses of the Examples. Further, while the depth of the surface compressive stress layer of ordinary soda lime glass (example 66) is, for example, about 15 the depth of the surface compressive stress layer of each of the glasses of the example 1, the example 27, the example 33, and the examples 39 to 43 being the Examples is larger than that of the soda lime glass, and it is inferred that the glass having high strength even after the chemical strengthening is obtained.

In order to confirm a color change property due to the long-term use of the glasses, the following evaluation test was conducted. Samples fabricated in such a manner that the glass samples of the example 1 and the example 58 were each cut into a 30 mm-square plate shape and both surfaces of the resultants were optically polished so as to have a predetermined thickness were disposed at a 15 cm position from a mercury lamp (H-400P), and spectral transmittances before and after 100-hour ultraviolet radiation were measured.

Next, variations ΔT (550/600) and ΔT (450/600) of the relative values of the absorption constants, shown by the following expressions (1), (2) were calculated. The results are shown in Table 11.

ΔT(550/600)(%)=[{A(500/600)−B(550/600)}/A(500/600)]×100 (1)

ΔT(450/600)(%)=[{A(450/600)−B(450/600)}/A(450/600)]×100 (2)

(In the above expression (1), A(550/600) is a relative value of an absorption constant at 550 nm wavelength and an absorption constant at 600 wavelength nm, as calculated from a spectral transmission curve of the glass after 100-hour irradiation with light of a 400 W high-pressure mercury lamp, and B(550/600) is a relative value of an absorption constant at 550 nm wavelength and the absorption constant at 600 nm wavelength, as calculated from a spectral transmittance curve of the glass before the light irradiation. In the above expression (2), A(450/600) is a relative value of an absorption constant at 450 nm wavelength and an absorption constant at 600 nm wavelength, as calculated from a spectral transmission curve of the glass after the 100-hour irradiation with the light of the 400 W high-pressure mercury lamp, and B(450/600) is a relative value of an absorption constant at 450 nm wavelength and an absorption constant at 600 nm wavelength, as calculated from a spectral transmittance curve of the glass before the light irradiation.)

TABLE 11

| | |
|---|---|
| Example 1 | Example 58 |
| Plate thickness: 0.714 mm | Plate thickness: 0.780 mm |

| | Before light | After light | Before light | After light |
|---|---|---|---|---|
| | irradiation | irradiation | irradiation | irradiation |
| (1) Absorption constant at 600 nm wavelength | 5.347 | 5.375 | 1.100 | 1.108 |
| (2) Absorption constant at 550 nm wavelength | 4.208 | 4.243 | 0.873 | 0.877 |
| (3) Absorption constant at 450 nm wavelength | 4.138 | 4.117 | 1.007 | 1.014 |
| Relative value of absorption constants | 0.787 | 0.789 | 0.793 | 0.791 |
| (@550 nm/@600 nm) *1 | | | | |
| Relative value of absorption constants | 0.774 | 0.766 | 0.916 | 0.915 |
| (@450 nm/@600 nm) *2 | | | | |

| | | |
|---|---|---|
| ΔT(550/600) [%] | 0.30 | −0.30 |
| ΔT(450/600) [%] | −1.04 | −0.07 |

*1 calculated by a calculation equation of (2)/(1) based on the absorption constants at the respective wavelengths
*2 calculated by a calculation equation of (3)/(1) based on the absorption constants at the respective wavelengths

As shown in Table 11, in the glasses of the example 1 and the example 58, absolute values of the variations ΔT (550/600) and ΔT (450/600) calculated from the relative values of the absorption constants before and after the ultraviolet irradiation are 5% or less, from which it is understood that these glasses are free from a color change due to a long-term use, and can maintain their initial outer color for a long period.

Further, absorption constants at wavelength from 380 nm to 780 nm were found also for the glasses after the aforesaid chemical strengthening in the same manner, and it was confirmed that their values were not different from those before the chemical strengthening. Further, it was also confirmed that they suffered no visual change in color tone. Therefore, the colored glass housing of the embodiments described herein is usable in the requiring strength owing to the chemical strengthening, without losing a desired color tone, and its use range is expanded to the application requiring a decorative function.

In order to confirm a radio wave transmission property of the glass, the following evaluation test was conducted. First, the glasses of the example 1 and the example 27 were worked to 50 mm×50 mm×0.8 mm by cutting and their main surfaces were polished to a mirror state. Then, dielectric tangent of the glasses at frequencies of 50 MHz, 500 MHz, 900 MHz, and 1.0 GHz were measured with the use of a LCR meter and an electrode by a capacitance method (parallel plate method). Measurement results are shown in Table 12. Note that a dielectric constant (6) of the glasses at the 500 MHz frequency was 7.6.

TABLE 12

| | | Example 1 | Example 27 |
|---|---|---|---|
| Frequency | | tan δ | tan δ |
| 50 | MHz | 0.007 | 0.006 |
| 500 | MHz | 0.007 | 0.006 |
| 900 | MHz | 0.007 | 0.005 |
| 1.0 | GHz | 0.007 | 0.004 |

As shown in Table 12, it is understood that these glasses have a good radio wave transmission property, with the dielectric tangent thereof at the frequencies in the 50 MHz to 1.0 GHz range being less than 0.001.

Next, Examples of the glass ceramics being the glass of the second embodiment will be described. Glass raw materials were compounded so that the glasses of the Examples each contain 8.7% Li₂O, 14% Al₂O₃, 70.3% SiO₂, 0.6% BaO, 1.5% TiO₂, 1.2% ZrO₂, 0.3% P₂O₅, 1.0% Na₂O, 0.7% K₂O, 0.2% As₂O₃, and 1.5% V₂O₅ in terms of molar percentage and they were melted at 1750° C. for ten hours. Next, the molten glass solution was molded by a roll-out plate making method while the glass was cooled, whereby a glass ceramics plate with a thickness of 2 mm was fabricated. Thereafter, it was kept at 750° C. for one hour, whereby a crystal nucleus was formed in the glass, and the glass was heat-treated at 900° C. for 15 minutes to be crystallized.

Regarding this glass ceramics, spectrophotometry was conducted regarding each sample of the aforesaid plate-shaped glass by using an ultraviolet-visible/near-infrared spectrophotometer (manufactured JASCO Corporation, product name: UV-IR spectrophotometer V-570), and a thickness of the glass was measured by a caliper. From these results, the absorption constants were calculated. As a result, the minimum value of the absorption constant at 380 nm to 780 nm wavelengths was 1.5 mm⁻¹ or more, and thus it has been confirmed that the glass has a high light blocking property.

Further, when flexural strength of the glass ceramics was measured, it was 150 MPa, and it was confirmed that the glass ceramics has high strength compared with glass not having undergone the chemical strengthening or the like.

According to the colored glass housing of the embodiments, it is possible to obtain a colored glass housing having a light blocking property suitable for a housing of an electronic device, at low cost without providing a light blocking means on glass.

Further, the colored glass housing of the embodiments is suitably usable also in the application requiring high strength.

Further, the portable electronic device of the embodiments has high strength, can reduce manufacturing cost, and is excellent in aesthetic appearance.

According to the colored glass housing of the embodiments, it is possible to provide one high in light blocking property and strength and excellent in manufacturing cost and aesthetic appearance, as a housing member provided on an exterior of an electronic device, for example, a portable electronic device.

What is claimed is:

1. A colored glass housing, comprising
a glass with an absorption constant having a minimum value of 1 mm⁻¹ or more at wavelength from 380 nm to 780 nm,
wherein the colored glass housing is configured to enclose an electronic device.

2. A colored glass housing, comprising
a plate made of glass, the plate having an absorbance of a minimum value of 0.7 or more at wavelength from 380 nm to 780 nm,
wherein the colored glass housing is configured to enclose an electronic device.

3. The colored glass housing according to claim 2,
wherein the plate is made of glass with an absorption constant having 1 mm⁻¹ or more at wavelength from 380 nm to 780 nm, and the plate has a thickness of 5 mm or less.

4. The colored glass housing according to claim 1 or 2,
wherein the glass contains at least one component as a coloring component selected from a group consisting of oxides of Co, Mn, Fe, Ni, Cu, Cr, V, and Bi amounting to 0.1% to 7% in terms of molar percentage on an oxide basis.

5. The colored glass housing according to claim 4,
wherein the coloring component in the glass is composed of: 0.01% to 6% of Fe₂O₃; 0% to 6% of Co₃O₄; 0% to 6% of NiO; 0% to 6% of MnO; 0% to 6% of Cr₂O₃; and 0% to 6% of V₂O₅ in terms of molar percentage on an oxide basis.

6. The colored glass housing according to claim 1 or 2,
wherein the glass contains: 55% to 80% of SiO₂; 3% to 16% of Al₂O₃; 0% to 12% of B₂O₃; 5% to 16% of Na₂O; 0% to 4% of K₂O; 0% to 15% of MgO; 0% to 3% of CaO; 0% to 18% of ΣRO (where R represents Mg, Ca, Sr, Ba, and Zn); 0% to 1% of ZrO₂; and 0.1% to 7% of a coloring component having at least one component selected from the group consisting of oxides of Co, Mn, Fe, Ni, Cu, Cr, V, and Bi in terms of molar percentage on an oxide basis.

7. The colored glass housing according to claim 6,
wherein the glass contains: 60% to 80% of SiO₂; 3% to 15% of Al₂O₃; 5% to 15% of Na₂O; 0% to 4% of K₂O; 0% to 15% of MgO; 0% to 3% of CaO; 0% to 18% of ΣRO (where R represents Mg, Ca, Sr, Ba, and Zn); 0% to 1% of ZrO₂; 1.5% to 6% of Fe₂O₃; and 0.1% to 1% of Co₃O₄ in terms of molar percentage on an oxide basis.

8. The colored glass housing according to claim 6,
wherein the glass contains: 55% to 80% of SiO₂; 3% to 16% of Al₂O₃; 0% to 12% of B₂O₃; 5% to 16% of Na₂O; 0% to 4% of K₂O; 0% to 15% of MgO; 0% to 3% of CaO; 0% to 18% of ΣRO (R represents Mg, Ca, Sr, Ba, and Zn); 0% to 1% of ZrO₂; 0.01% to 0.2% of Co₃O₄; 0.05% to 1% of NiO; and 0.01% to 3% of Fe₂O₃ in terms of molar percentage on an oxide basis.

9. The colored glass housing according to claim 6,
wherein the glass contains 0.005% to 2% of a color correction component having at least one component selected from a group consisting of oxides of Ti, Ce, Er, Nd, and Se.

10. The colored glass housing according to claim 1 or 2,
wherein a value of an absorption constant of the glass at 550 nm wavelength/an absorption constant of the glass at 600 nm wavelength and a value of an absorption constant of the glass at 450 nm wavelength/the absorption constant of the glass at 600 nm wavelength are both within a range of 0.7 to 1.2.

11. The colored glass housing according to claim 1 or 2,
wherein absolute values of variations ΔT (550/600) and ΔT (450/600) calculated from relative values of the absorption constants of the glass as expressed by the following expressions (1), (2) are 5% or less:
ΔT(550/600)(%)=[{A(550/600)−B(550/600)}/A(550/600)]×100 (1); and
ΔT(450/600)(%)=[{A(450/600)−B(450/600)}/A(450/600)]×100 (2),
where in the above expression (1), A (550/600) is a relative value of the absorption constant at 550 nm wavelength and the absorption constant at 600 nm wavelength, as calculated from a spectral transmittance curve of the glass after 100-hour irradiation with light of a 400 W high-pressure mercury lamp, and B(550/600) is a relative value of the absorption constant at 550 nm wavelength and the absorption constant at 600 nm wavelength, as calculated from a spectral transmittance curve of the glass before the irradiation with the light; in the above expression (2), A (450/600) is a relative value of the absorption constant at 450 nm wavelength and the absorption constant at 600 nm wavelength, as calculated from a spectral transmittance curve of the glass after the 100-hour irradiation with the light of the 400 W high-pressure mercury lamp, and B (450/600) is a relative value of the absorption constant at 450 nm wavelength and the absorption constant at 600 nm wavelength, as calculated from a spectral transmittance curve of the glass before the irradiation with the light.

12. The colored glass housing according to claim 1 or 2,
wherein the glass is glass ceramics.

13. The colored glass housing according to claim 1 or 2,
wherein the glass is chemically strengthened glass.

14. The colored glass housing according to claim 13,
wherein the glass has a compressive stress layer formed by chemical strengthening at a depth of 6 μm to 70 μm from a surface thereof.

15. The colored glass housing according to claim 14,
wherein the compressive stress layer is the depth of 30 μm or more, and a surface compressive stress of the glass is 550 MPa or more.

16. The colored glass housing according to claim 1 or 2,
wherein the electronic device is a portable electronic device.

17. A portable electronic device comprising the colored glass housing according to claim 1 or 2,
wherein the colored glass housing is configured to enclose the portable electronic device.
